(19) United States
(12) Patent Application Publication
(10) Pub. No.: US 2011/0074504 A1
(43) Pub. Date: Mar. 31, 2011

(54) MULTI MODE POWER OUTPUT MODULE AND METHOD OF USE WITH AN RF SIGNAL AMPLIFICATION SYSTEM

(76) Inventor: Sei-Joo Jang, Seoul (KR)

(21) Appl. No.: 12/964,391

(22) Filed: Dec. 9, 2010

Related U.S. Application Data
(63) Continuation-in-part of application No. 12/363,725, filed on Jan. 31, 2009.
(60) Provisional application No. 61/374,421, filed on Aug. 17, 2010.

(30) Foreign Application Priority Data
Dec. 4, 2009 (KR) 10-2009-0119496
Dec. 21, 2009 (KR) 10-2009-0127826

(51) Int. Cl. H03F 3/68; H03G 1/00

(52) U.S. Cl. 330/124 R; 330/127

(57) ABSTRACT

A multi mode power output module for use with RF signal amplification system. The multi mode power output module includes at least two power sources; a multiple of output power circuits associated with each of the at least two power sources; a first switch to switch between the at least two power sources, where the first switch provides power from at least two power sources to the output power circuit to amplify an RF signal associated with a lowest power output level; and second switch to switch between an RF output and the multiple of output power circuits to select a output power circuit associated with one of the at least two power sources that is also connected to the RF output.

This application is a continuation-in-part application of U.S. patent application Ser. No. 12/363,725 filed on Jan. 31, 2009 and claims the benefit of and incorporates by reference U.S. patent application Ser. No. 12/363,725 and U.S. Provisional Application 61374421, filed on Aug. 17, 2010.

This application claims the benefit under Title 35, United States Code, Section 119 and incorporates by reference Korean applications 10-2009-0119496, filed Dec. 4, 2009 and 10-2009-0127826, filed Dec. 21, 2009.

### BACKGROUND

Mobile telecommunication networks employ stationary communication units such as base stations and repeaters to allow communications between wireless devices, such as cell phones and computers. The repeaters are used between the base station and wireless devices to enhance the quality of the RF signal, extent service area around the base stations and reduce the cost of the network. The output power of a base station can be as large as five hundred Watts. The average output power of a repeater varies from zero to sixty Watts. However, the power output efficiency of the mobile telecommunication equipment used in stationary communication units is notoriously “low” at about ten percent.

One of the reasons for such low power efficiency of mobile telecommunication equipment relative to other power applications is that the quality of RF signal radiated to open space needs to be extremely high. The high quality signal is necessary for preventing interference among high bit rate signals from different service providers in common open space. Among several characteristics in the radiation of an RF signal, Adjacent Channel Leakage Ratio (ACLR) and Error Vector Magnitude (EVM) are two most important output signal characteristics to be considered.

The optimum efficiency of a Power Amplifier (PA) can be obtained, in general, when the PA is operating at near its saturation point. Most PAs exhibit some degree of nonlinearity near the PA's saturation point, which causes an increase in the spectral growth of the output power density and leads to distortion of the ACLR and EVM of the output signal. Conventional PAs employed in typical amplification systems are designed to operate within a linear region prior to the saturation point of the PA. The conventional Pas operate with in the linear region to satisfy the ACLR and EVM requirements, but consequently sacrifice efficient operation of the PA.

Several methods, such as a Digital Pre-Distortion (DPD), a Adaptive Pre-Distortion (APD) (U.S. Pat. No. 7,026,873 B2, Apr. 11, 2006), Adaptive Feed Forward Linearization(AFL) and Doherty Amplifier (both Symmetry and Asymmetry) have been developed to extend the linear response of PAs and consequently improve the efficiency of the PA. It is clear that the higher power output efficiency would contribute reducing both the total network cost and amount of green house gases.

Wireless services have become complex due to the increasing demand of higher quality, faster speed and various contents in wireless system. The demand for the higher speed and larger capacity wireless telecommunication network is becoming important due to the rapidly increasing data traffic due to heavy use of mobile internet. There are several ways to increase the capacity of wireless networks. One option is deploying faster and larger capacity networks, which might be the simplest way, but will probably be the most expensive way. Another option is the development of an innovative way to increase the network capacity by enhancing the speed of data bit rates in the existing networks. A very high quality signal with superior ACLR and EVM signal may be needed to increase the bit rates and the speed of data delivery during the heavy data traffics in a dense population environment in order to provide high quality service.

A third option is employing a new innovative wireless network system using cognitive radio (CR) and/or software defined radio (SDR) systems. Where CR is a paradigm for wireless communication in which either a network or a wireless node changes its transmission or reception parameters to communicate efficiently avoiding interference with licensed or unlicensed users. This alteration of parameters is based on the active monitoring of several factors in the external and internal radio environment, such as radio frequency spectrum, user behavior and network state. SDR is a radio communication system where components that have been typically implemented in hardware (e.g. mixers, filters, amplifiers, modulators/demodulators, detectors, etc.) are instead implemented by means of software on computing devices. While the concept of SDR is not new, the rapidly evolving capabilities of digital electronics render practical many processes which used to be only theoretically possible. Software radios have significant utility for the military and cell phone services, both of which must serve a wide variety of changing radio protocols in real time. The CR and SDR can utilize the available white space frequencies.

White space frequencies refer to frequencies allocated to a broadcasting service but not used locally. National and international bodies assign different frequencies for specific uses, and in most cases license the rights to broadcast over these frequencies. This frequency allocation process creates a bandplan, which for technical reasons assigns white space between used radio bands or channels to avoid interference. In this case, while the frequencies are unused, they have been specifically assigned for a purpose, such as a guard band. Most commonly however, these white spaces exist naturally between used channels, since assigning nearby transmissions to immediately-adjacent channels will cause destructive interference to both. In addition to white space assigned for technical reasons, there is also unused radio spectrum which has either never been used, or is becoming free as a result of technical changes. In particular, the switchover to digital television frees up large areas between about 50 MHz and 700 MHz. This is because digital transmissions can be packed into adjacent channels, while analog ones cannot. This means that the band can be “compressed” into fewer channels, while still allowing for more transmissions. In the United States, the abandoned television frequencies are primarily in the upper UHF “700-megahertz” band, covering TV channels 52 to 69 (698 to 806 MHz). U.S. television and its white spaces will continue to exist in UHF frequencies, as well as VHF frequencies for which mobile users and white-space devices require larger antennas. In the rest of the world, the abandoned television channels are VHF, and the resulting large VHF white spaces are being reallocated for the worldwide digital radio standard DAB and DAB+, and DMB.

It is an object of the present invention to multi modes of output circuits.

### SUMMARY OF INVENTION

A multi mode power output module for use with RF signal amplification system. The multi mode power output module includes at least two power sources; a multiple of output power circuits associated with each of the at least two power sources; a first switch to switch between the at least two power sources, where the first switch provides power from at least two power sources to the output power circuit to amplify an RF signal associated with a lowest power output level; and second switch to switch between an RF output and the multiple of output power circuits to select a output power circuit associated with one of the at least two power sources that is also connected to the RF output.

### BRIEF DESCRIPTION OF THE DRAWING

FIG. 1 is a schematic diagram of a front end input circuit using a switching filter bank according to the present invention.

FIG. 2 is a schematic diagram of an output power circuit using a switching filter bank according to the present invention.

FIG. 3 is a schematic diagram of the wireless equipment with input and output circuits according to present invention.

FIG. 4 is a schematic view of an amplification system according to the present invention.

FIG. 5 is a schematic view of two band pass filters connected in series according to the present invention.

FIG. 6a schematic view of a plurality of band pass filters connected in series according to the present invention.

FIG. 7 is a schematic view of WIBRO repeater with the amplification system according to the present invention.

FIG. 8 is a representation of principles of pre-distorter linearization according to the present invention.

FIG. 9 is a schematic view of DPD according to the present invention.

FIG. 10 is a schematic view of DPD with the amplification system according to the present invention.

FIG. 11 is a schematic view of signal and error cancellation with the amplification system according to the present invention.

FIG. 12 is a schematic view of the amplification system according to the present invention.

FIG. 13 is a schematic view of the amplification system according to the present invention.

FIG. 14 is a schematic view of the amplification system according to the present invention.

FIG. 15 is a schematic view of the amplification system according to the present invention.

FIG. 16 is a schematic view of the amplification system according to the present invention.

FIG. 17 is a schematic view of a Doherty amplifier used as an LA according to the present invention.

FIG. 18 is a schematic view of the amplification system according to the present invention.

FIG. 19 is a schematic view of the amplification system according to the present invention.

FIG. 20 is a schematic view of the amplification system according to the present invention.

FIG. 21 is a schematic diagram of two power amplifiers connected in parallel to a final power Amp, DA(3) according to the present invention.

FIG. 22 is a schematic diagram of an equivalent circuit of FIG. 21 according to the present invention.

FIG. 23 is a schematic diagram of the output power module with PD ENGINE and three DA for in-phase coherent two input signals combination with filter module and Doherty amplifier according to the present invention.

FIG. 24 is a schematic diagram of the output power module of FIG. 23 with AFL according to the present invention.

FIG. 25 is a schematic diagram of one example of an output circuit according to according to the present invention.

FIG. 26 is a schematic diagram of a multi mode power output module according to the present invention.

FIG. 27 is a schematic diagram of a multi mode power output module according to the present invention.

### DETAILED DESCRIPTION OF THE INVENTION

The present invention is a flexible wireless network system and method of use. The flexible wireless network includes advanced switching and amplification to increase power output and quality of RF signals used with wireless networks. The flexible wireless network system is a network that allows the used of different frequencies on a temporary basis, such as the utilization of white space frequencies for wireless communication and data transfer. The flexible wireless network system allows for the accommodation of ever increasing data traffic and customer demands for higher quality affordable wireless communication services. The flexible wireless network system includes improved RF signal amplification at the input of a stationary communication unit and improved output power at the output of the stationary communication unit, in order to provide improved signal to noise ratio values. The flexible wireless network system includes methods to provide a high quality output signal for high bit rates and to provide a high output power efficiency. The flexible wireless network system takes in account Pre-Distortion including the Adaptive Pre-Distortion (APD) and Digital Pre-Distortion (DPD) and incorporates a Filter Module (FM) to further enhance the output power efficiency and the quality of an output RF signal. The flexible wireless network system includes utilizing the principles of coherent multi-wave combination properties similar to lasers to improve the quality of the input signal to the Doherty Amplifier and consequently to enhance output power efficiency of the Doherty Amplifier. The flexible wireless network system incorporates Adaptive Feed Forward Linearization (AFL) methods to enhance output power efficiency.

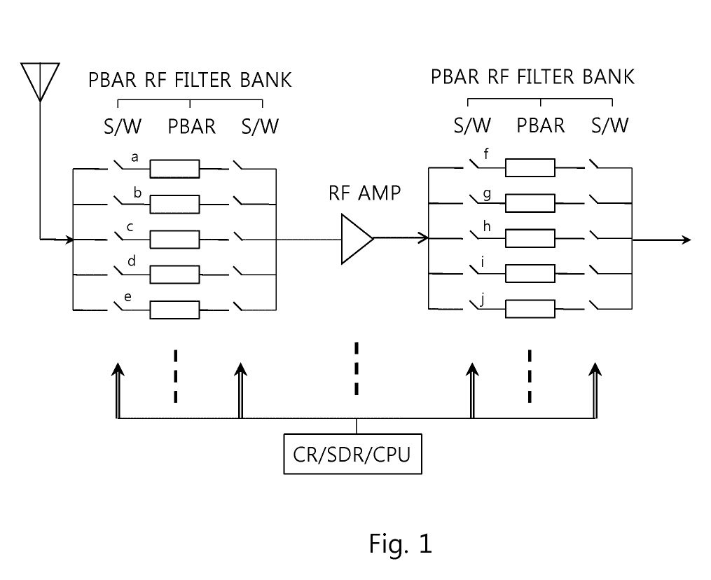

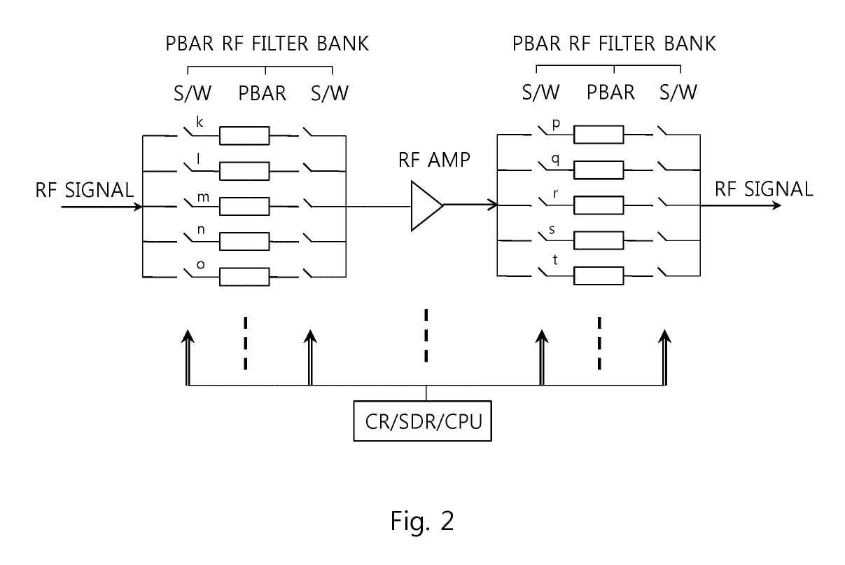

Improved desired signal selectivity at the input of a communication unit and improved output power at the output of the stationary communication unit both include the use of a filter bank using bulk acoustic resonators. FIG. 1 shows schematic diagram of the front end input circuit using a filter bank made up a series of polymer bulk acoustic resonators a-e and f-j with switching. The improved selectivity capability of an RF signal at the input of a communication unit comes from the use of the filter bank made up a series of polymer bulk acoustic resonators with switching shown in FIG. 1. The polymer bulk acoustic resonators a-e and f-j are used as filters to enhance the signal/noise ratio of the inputted RF signal. FIG. 1 shows an input source 12 as antenna that can receive RF signals connected to front end input circuit. The input source 12 can also be a cabled source that delivers the RF signal. For example, a digital signal over fiber optic cable could be converted into an RF signal and delivered to the input source. FIG. 2 shows schematic diagram of an output circuit using a filter bank made up a series of polymer bulk acoustic resonators k-o and p-t with switching. The improved output power at the output of the stationary communication unit comes from the use of the filter bank made up a series of polymer bulk acoustic resonators with switching shown in FIG. 2.

A polymer bulk acoustic resonator utilizes piezoelectric Electro-Active Polymers (EAP) as the thin film materials for manufacturing the bulk acoustic resonator. The manufacture of the polymer bulk acoustic resonator employs a new approach in order to co-process active semiconductor materials such as Si, SiGe, GaN or GaAs with passive high frequency filter piezoelectric polymer materials of EAP. Recent development of active polymer semiconductors allow for active devices, such as switches and amplifiers which can be processed together with passive devices such as filters. By using EAP materials for passive filter devices, one can readily and cost effectively produce integrated modules of a passive filter bank along with active switches and amplifiers for wireless mobile telecommunication network equipment. As well, by using EAP materials for active polymer semiconductor switches and/or amplifiers, costs can be reduced. The operating frequency of the polymer bulk acoustic resonator depends primarily on the thickness, density and bulk modulus of the EAP materials, which can be in the range of about 100 MHz to 30 GHz. The sound velocity (v) for EAP materials ranges from fifteen-hundred (1500) to two-thousand (2000) meters per second. For a given resonant frequency f_{R}, there is the equation f_{R}=v/(2*(thickness of the EAP)). Therefore, the thickness of EAP films for 1 GHz, 3 GHz, and 10 GHz resonant frequencies are 0.75 um, 0.25 um, and 0.075 um, respectively. The polymer bulk acoustic resonator usually includes an active semiconductor layer; a first thin film electrode layer applied to the semiconductor layer; a thin film electro-active polymer layer applied to the first thin film electrode layer; and a second thin film electrode layer applied to the thin film electro-active polymer layer. The polymer bulk acoustic resonator can also include a Bragg Reflector or a reduced Bragg Reflector applied between the first thin film electrode layer and the thin film electro-active polymer layer. The polymer bulk acoustic resonator can also include where the first thin film electrode layer applied to the semiconductor layer is a heavy metal film of high acoustic impendence to improve acoustic isolation of the thin film electro-active polymer layer applied to the first thin film electrode layer. The polymer bulk acoustic resonator usually is made such that the acoustic impedance of the electro-active polymer layer is not similar to acoustic impedance of the semiconductor layer. The silicone or polymer semiconductor layer of the polymer bulk acoustic resonator from can include at least one switch, at least one amplifier or at least one signal processor. The electro-active polymer layer of the polymer bulk acoustic resonator can be used as a frequency signal filter.

Each polymer bulk acoustic resonator a-s of FIGS. 1 and 2 act as a filter for a specific frequency or bandwidth of frequencies. Therefore for instance resonator a of the first bank shown in FIG. 1 could be for a one specific frequency or frequency band and resonator e of the second bank shown in FIG. 1 would also be for that same frequency. The same is true for the resonators of FIG. 2. Switches (S/W) are provided to each end of each resonator, so that each resonator can be switched open or closed. Therefore, when the switches are closed for one resonator and open for the rest of the resonators, an input frequency matching the resonator with the closed switch will pass from the input source to that polymer bulk acoustic resonator of the first filter bank, on through RF amplifier, through polymer bulk acoustic resonator of the second filter bank to be outputted from the filter bank to its next destination. The opening and closing of switches of each resonator of each filter bank is controlled by the CR, SDR or other computer device. This because an antenna as an input source can receive a multiple of frequencies and the CR, SDR or other computer device is used select the desired frequency or band of frequencies which are desired to pass through the system by switching close the resonators which will allow the desired frequency to pass. The output circuit of FIG. 2 uses filter banks made up a series of polymer bulk acoustic resonators with switching that are in sync with the filter banks of the input circuit of FIG. 1 to allow the same frequency to pass. Where the RF signal is processed through the first filter bank of FIG. 2 through a selected polymer bulk acoustic resonator that is selected based on its frequency, as determined by CR, SDR or other computer device. The input RF signal passes through the RF amp and into the selected polymer bulk acoustic resonator of the second filter bank of FIG. 2. The white space frequency allowed through the filter banks of FIGS. 1 and 2 is chosen by the CR, SDR or/and computer system. With the switching filter bank made of PBAR in FIGS. 1 and 2, the pre-determined wide ranges of white space frequencies can be processed through the wireless equipment system.

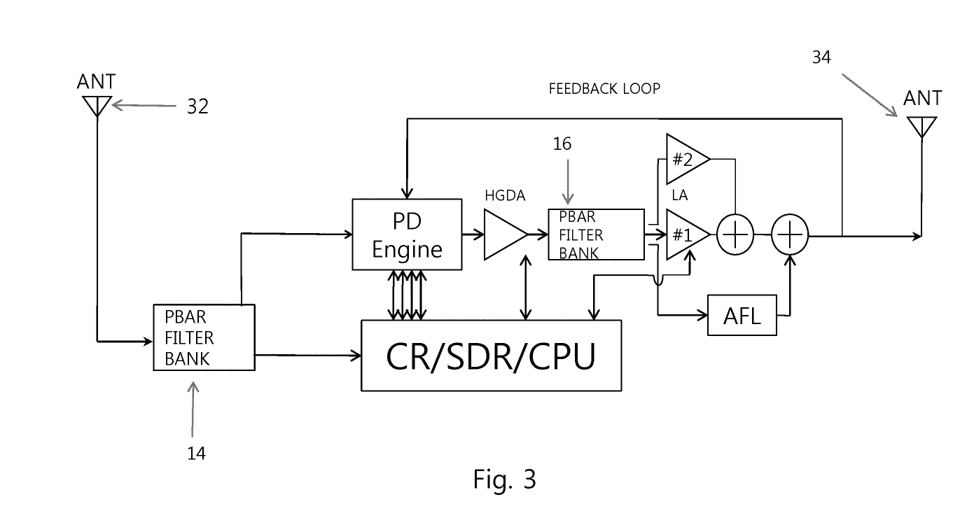

FIG. 3 is a schematic diagram of wireless equipment with an input circuit of FIG. 1 shown as the PBAR FILTER BANK 14 and output circuit of FIG. 2 shown as the PBAR FILTER BANK 16. The PBAR FILTER BANK 14 acts as an input filter bank and the PBAR FILTER BANK 16 as a filter module. The concepts of the other components of FIG. 3 require some further explanation before they are defined. In order to suppress interference during amplification of a either an input RF signal or an output RF signal in mobile telecommunication equipment, while increasing RF power output efficiency. The present invention is also a method of implementing the suppression of interference in mobile telecommunication equipment, while increasing RF power output efficiency of the in mobile telecommunication equipment and maintaining the required ACLR and EVM values.

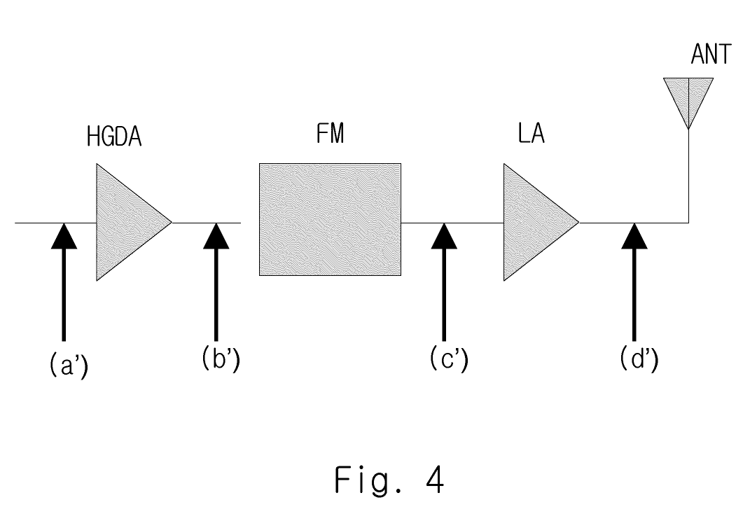

RF power output efficiency is defined as: total RF radiation power of the stationary communication unit divided by DC electric power required by an output power amplifier of the stationary communication unit in order to generate that total RF radiation power. FIG. 4 shows a High Gain Driving Amplifier (HGDA), Filter Module (FM), and a Linearization RF Power Amplifier (LA). The input RF signal to be amplified and outputted enters at point (a′) into the HGDA, as depicted in FIG. 4. The HGDA is a high gain amplifier. The function of HGDA is to generate a large pre-determined gain to the input RF signal and deliver the amplified RF signal to the FM and the LA. A magnitude of gain in the range of about 60 dB to 80 dB is envisioned at the HGDA, which is much larger than that of conventional driving amplifiers in current use. A HGDA is chosen based on the amplifier's output level and optimizing the amplifier's efficiency, and is less concern with its output signal quality. This is because the input RF signal to the LA will be improved significantly by the FM. The FM includes one or more Band Pass Filters (BPF). The FM can also include additional components to improve the signal processing of the first amplified version of the input RF signal. The one or more BPF of the FM are used to improve the first amplified version of the input RF signal to meet ACLR requirements.

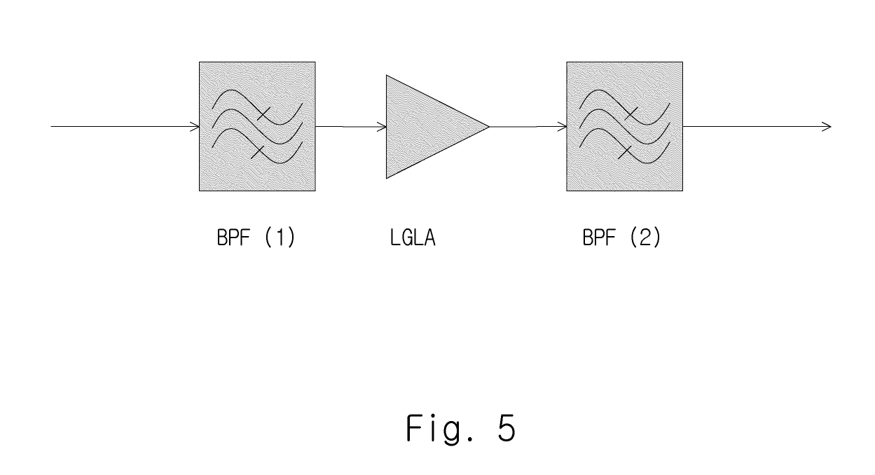

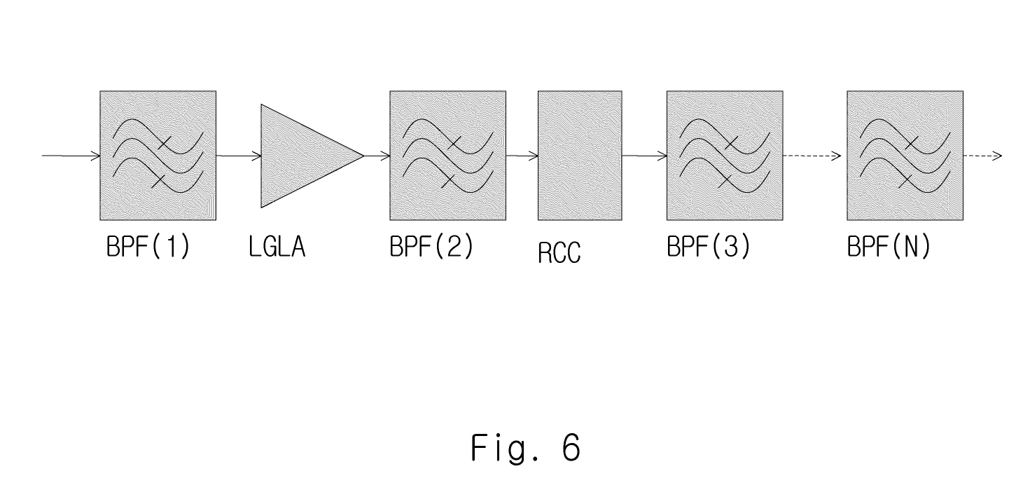

The FM is designed to produce an extremely clean signal with specific properties depending on the frequency bandwidth to pass through the FM. This is because the LA is to be designed to operate at near its saturation point for optimum power output efficiency with the pass-in quality. When more than one RF band pass filter is used, there can be a combination of all above different types of RF band pass filters. By connecting several high quality RF band pass filters in series, the ability to obtain larger isolation and skirt values is achieved. For an example, if a number “N” of RF band pass filters is connected in series, then the final isolation and skirt values will be N×(−50 dB) and “N×(−50 dB/delta f)”, respectively. Insertion loss and ripple will also increase by “N×(−5 dB)” and “N×(−5 dB)”, respectively. Insertion loss can be compensated for by installing a Low Gain Linear Amplifier (LGLA) between RF band pass filters, as shown in FIG. 5. The LGLA is usually a low gain linear power amplifier used to make up for signal loss during filtering of a signal. A more difficult task is the improvement of the ripple property, as the ripple property deteriorates by connecting several RF BPFs in series. Prevention of ripple property deterioration can be solved by connecting, in series, a ripple compensating circuit (RCC), as depicted in FIG. 6. The RCC can be designed by using known band stop or directional filters. The RCCs and LGLAs can be removed or reduced by designing or selecting RF BPFs properly. It is desirable to have a tunable impedance matching tunable circuit for coupling between each of the RCC, LGLA and RF BPF connected in series to optimize the coupling between them for the maximum output. The impedance matching tunable circuit between every two components in the FM can be important. Proper impedance matching of components in the FM reduces reflection of the signal when transitioning from one component to another component. Proper impedance matching is also important between the HGDA and FM, as well as between the FM and the LA.

The LA is a power amplifier having a gain of not much more than 20 dB to replace a conventional PA and to produce the second amplified version of the input RF signal that will be outputted. The LA is a low gain amplifier. The amplifier used as LA should be is operating at or near its saturation point when producing the gain in the RF signal, in order to provide that the amplifier used as the LA is operating at or near optimal efficiency of the amplifier.

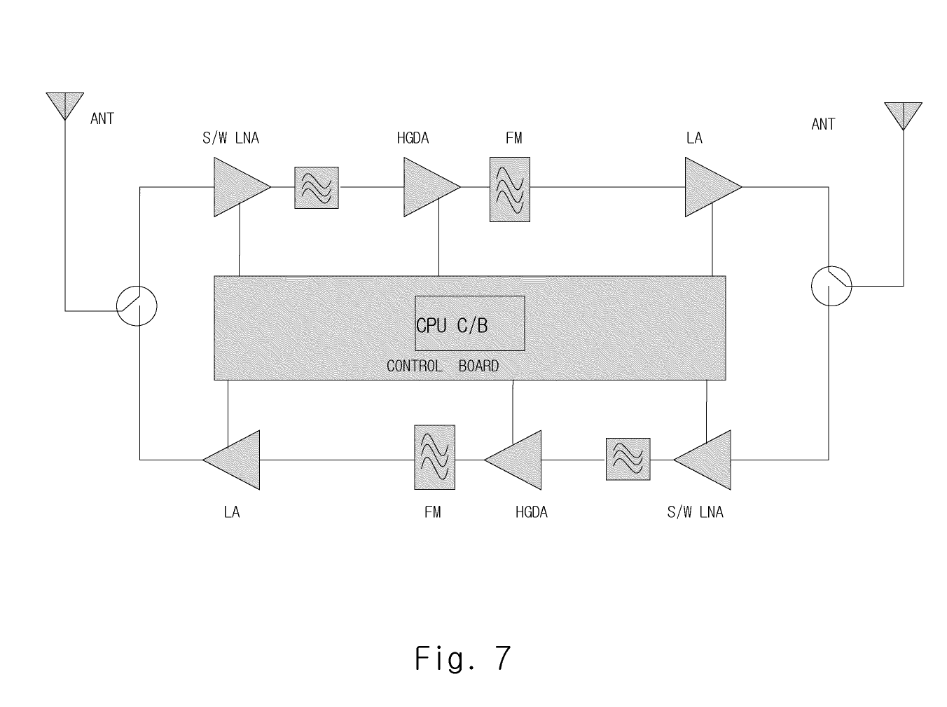

FIG. 7 shows a block diagram of a WIBRO repeater with the HGDA-FM-LA combination of FIG. 4 to provide for high RF output power efficiency. Antennas (ANT) are shown receiving and transmitting RF signals. An input RF signal from one or two ANT and amplified by an LGLA to an appropriate magnitude to supply an input RF signal to the HGDA is shown. The signal from the S/W LNA is amplified by HGDA to have a predetermined large enough gain in signal strength. This gain at the HGDA is filtered by FM to pass in-band signal and reject out-band noise sufficiently to obtain very a large isolation output signal from the FM. The signal from the FM supplies the LA with a cleaner version of the signal with the predetermined gain to provide for a desired magnitude RF output signal from the LA with satisfactory ACLR, EVM, and other required properties.

As a theoretical example, it will be explained how to determine the approximate amount of gain required at each amplifier of the HGDA-FM-LA combination. One of the variables that controls the output strength of the RF signal is gain at the LA, which has been determined to be optimal between 10 and 20 dB. If one desires an output RF signal of 100 Watt from a stationary communication unit, one would require a 50 dbm signal. One might choose an amplifier for the LA that has a 15 dB gain while operating at its saturation point. Therefore the strength of the signal from the FM should be 35 dBm, because 35 dBm plus 15 dB equals 50 dbm. It has been shown in experimentation that a properly designed FM causes a loss of −3 dB in signal strength. Therefore the signal strength should be at 38 dBm prior to entering the FM, in order to have a 35 dBm signal to enter the LA. Next, the strength of the input RF signal and the choice of the HGDA must be coordinated to produce a 38 dBm signal prior to entering the FM. As an example, the combination of an input RF signal of −32 dBm and a HGDA that generates a 70 dB gain while operating at its saturation point would produce a 38 dBm signal. The −32 dBm input RF signal is a signal that has been received and processed by the communication unit for various known reasons to be at −32 dBm. Working backwards in this manner during design produces a more precise amplification system that provides high gains while attempting to prevent self-oscillation due to parasitic feedback at the receiving antenna of the stationary communication unit.

The amplification system using the HGDA-FM-LA combination can produce gains in signal strength without sacrificing optimum power output efficiency. This because unlike the conventional systems currently in use, the two amplifiers employed are operating at or near optimal efficiency for each amplifier. The HGDA-FM-LA combination can be applied for the TDD (time division duplex) of WIBRO or mobile WIMAX, FDD (frequency division duplex) of WCDMA and again TDD of the 4^{th} generation LTE (Long Term Evolution) systems. In addition to above RF Power output efficiency enhancement by amplification system, the HGDA-FM-LA combination also contributes on the Higher Data Rate and Spectral Efficiency, which is the efficiency of data delivery capability of the communication network. For an example, the higher spectral efficiency system requires less RF power output to cover a certain area than for lower efficiency network system. This is because the quality of RF output signal and the capability of cleaning a noisier input signal are provided by using the HGDA-FM-LA combination.

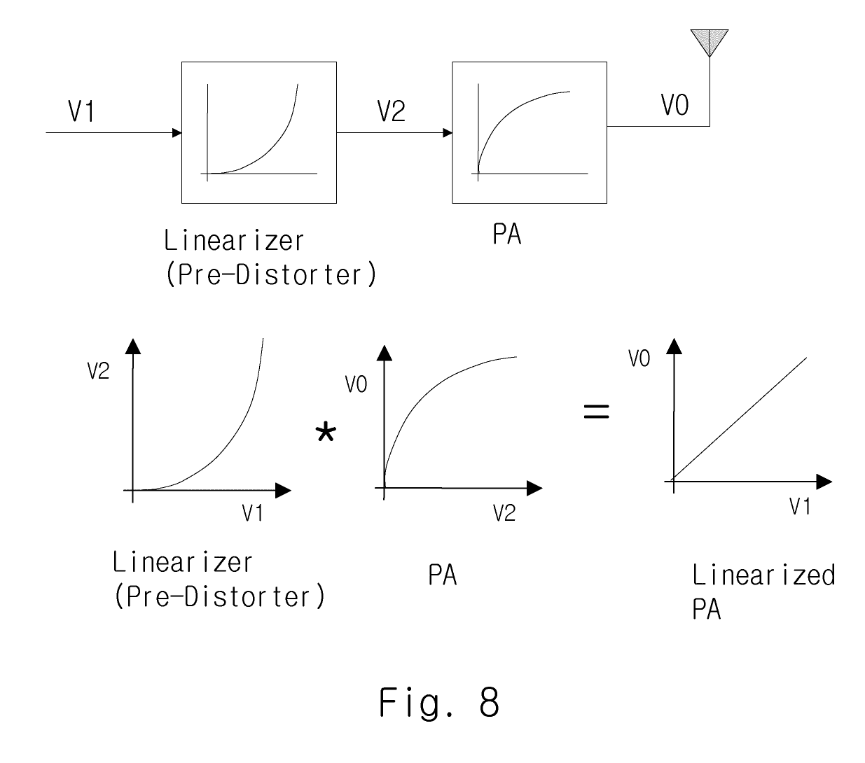

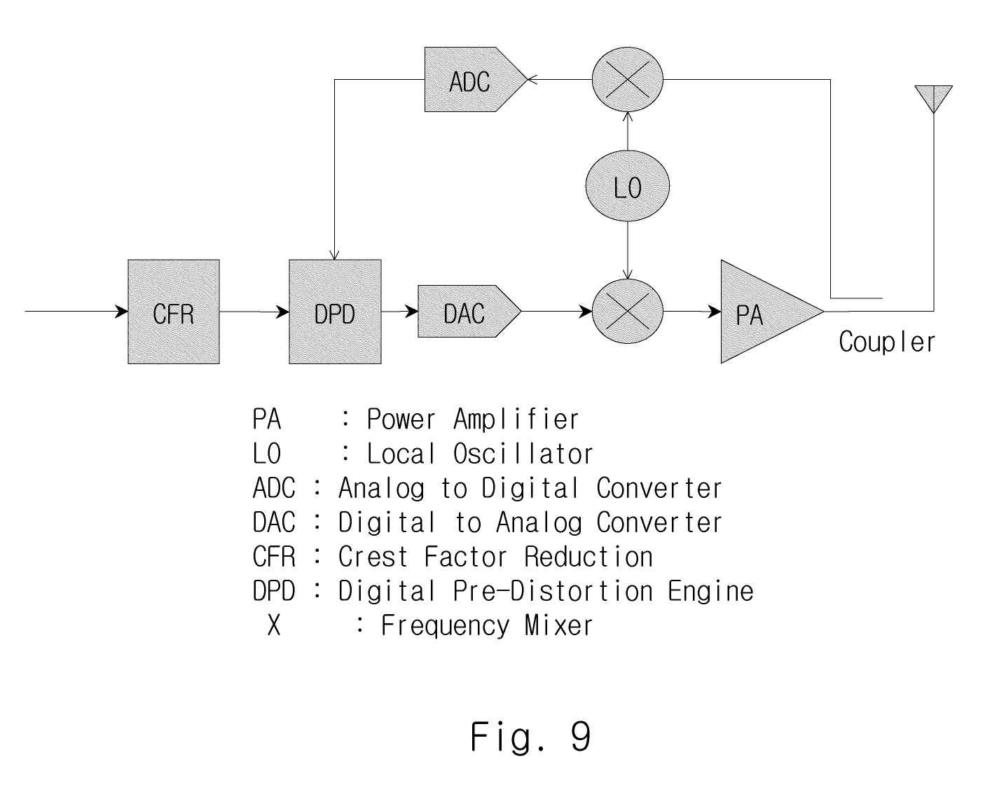

FIGS. 8 and 9 depict a known method that uses a signal processor referred to as Digital Pre-Distortion (DPD), which is used with the conventional PAs. FIG. 8 shows the DPD and the components used with the DPD to aid in processing the signal to be strengthened. FIG. 9 shows the principles of the DPD technique, where combine processing of the signal with the DPD and PA in a non linear state produces an output signal that has properties as if the signal were process by an amplifier that produces gain in a linear fashion. In DPD method, the input RF signal has been converted to a digital form before entering the Crest Factor Reduction unit (CFR), so that the signal may be processed by the DPD. The input RF signal is modified due to signal processing by the DPD engine in real time using the digital form of the input RF signal and using the digitally transformed feedback of the analog output signal from the PA at a coupler in such a way as to correct or improve the ACLR of the output power density spectrum. The signal from the DPD travels through an up converter frequency mixer than to the PA, but the signal must first be converted to analog using a Digital to Analog Converter (DAC). The feedback signal from the output signal of the PA is a small percentage of the output signal from the PA. That small percentage of the output signal from the PA is converted to a digital form by traveling through a down converter frequency mixer. The down converter frequency mixer attached after the ADC is also attached to a Local Oscillator (LO) to cause the down conversion of the frequency. The down converter frequency mixer outputs the converted signal to an Analog to Digital Converter (ADC). The converted digital of the feedback signal from the PA is fed back to the DPD. Note, that in FIG. 8, there is an up converter frequency mixer between the DPD and PA that is also attached to the LO. The up converter frequency mixer along with the LO up converts the signal from the DPD after it has left the DAC. The DPD method requires a very fast micro-processor and careful adjustment of whole circuit. The DPD method has been described in detail in reference, “RF and Microwave Circuit Design for Wireless Communication”, edited by L. E. Larson, Artech House (1996), Chapter 4.

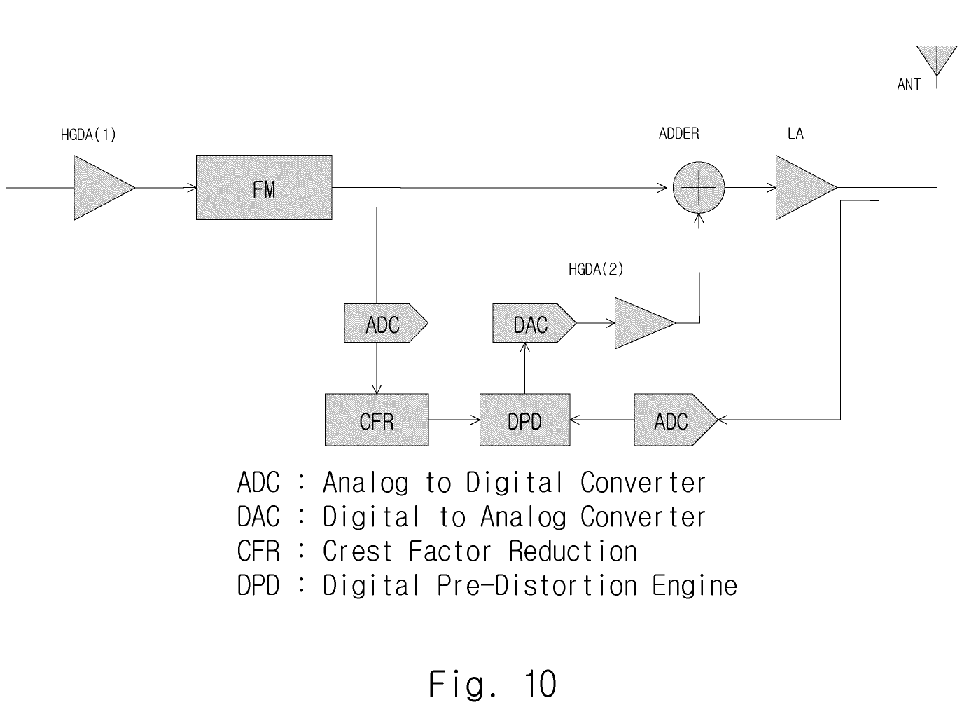

The use of the DPD method described above along with the present invention can further improve the efficiency of the output signal from the LA. FIG. 10 shows a high efficiency RF output power amplifying system incorporating both HGDA-FM-LA combination and DPD in parallel connection. Notice that the input RF signal is an analog signal from the FM and must be converted to a digital signal using the ADC before the RF signal from the FM enters the CFR of the DPD method. The output of the FM is coupled to the CFR to send part of the signal from the FM to the CFR. The signal from the FM to the CFR and DPD is a small percentage of the total signal outputted from the FM, whereby the remaining percentage of the signal is sent to LA through the Adder. The output signal from the LA is coupled to an ADC, such that a small percentage of the total signal outputted from the LA is sent to the ADC, whereby the remaining percentage of the signal is usually sent to an antenna. The signal that travels through the ADC is converted to a digital signal and is inputted to the DPD. The signals from the CFR and ADC are processed by the DPD according to known methods consistent with the DPD method. The end result of the processing by the DPD produces a modified signal that is outputted to a DAC for conversion from a digital signal to an analog signal. A second HGDA is used between the DPD and the LA. The second HGDA is used to amplify the analog signal from the DAC to be the similar strength as the signal from the FM to the Adder. The second HGDA does not necessarily have to be operated near its saturation point in the same manner as the first HGDA. Typically, the gain in signal strength is from 10 to 40 dBs at the second HGDA to achieve proper signal strength to the Adder. The Adder is a known device used to combine two or more signals to form one signal. The signal that is outputted from the Adder produces a modified signal that is sent to the LA. The result is an output signal that has further improved ACLR properties by using the DPD method.

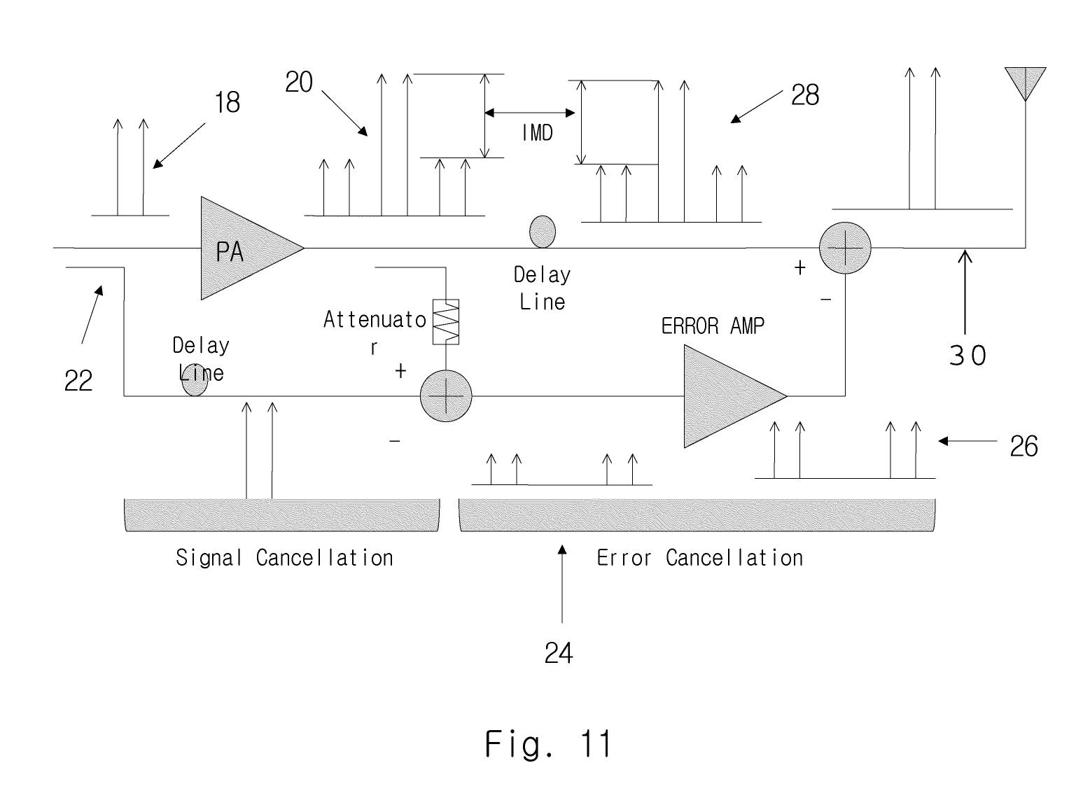

FIG. 11 depicts a known method Adaptive Feed Forward Linearization (AFL) with the conventional PAs of FIG. 1 in order to obtain a good quality ACLR output signal. AFL method improves the output signal by using the Inter-Modulation Distortion (IMD) portion of the output RF signal and subtracting an opposite polarity IMD signal that is similar in magnitude. The opposite polarity IMD signal is obtained by processing the signal that enters the PA, prior to that signal entering the PA and feeding the result forward to the output of the PA. The details of the AFL method are described in reference. “RF Microelectronics”, by B. Razavi, Prentice Hall (1998), Chapter 9. FIG. 11 shows the basics of how the AFL method is employed with a PA. The upward arrows indicate magnitude of the signal. The signal enters the PA have a minimal amount of distortion, as shown by the two upward arrows at 18. When the signal exits the PA, the signal is increased in magnitude as shown by the two middle arrows at 20, but the signal also includes distortion as indicated by the shorter arrows on either side of the two middle arrows. The magnitude of the shorter arrows represents the strength of IMD. The signal is delayed by a delay line device for timing. A small percentage of the signal that enters the PA is diverted by a coupler at 22 to a delay line. The two delay lines of the AFL provide proper timing for processing the signal that enters the PA. The signal at 22 is similar to the signal at 18, but is lower in magnitude. The signal at 22 is sent to an adder. A small percentage of the signal at 20 is sent to an attenuator to reduce the magnitude of the signal taken from the signal at 20. That signal is sent to the adder. Combining the signals at the adder using subtraction provides a signal at 24 that only includes the distortion portion (IMD) of the signal from 22. The signal at 24 is inputted to an error amp to increase the magnitude of the IDM signal to produce a signal at 26 which has a similar magnitude to the IMD signal exiting the delay line at 28. The error amp usually operates linearly with a gain from 10 to 40 dB. The signal at 26 is send to a second adder, as well is the signal at 28. The signal at 26 is subtracted from the signal at 28 to produce a final output signal at 30 that does not possess the distortion.

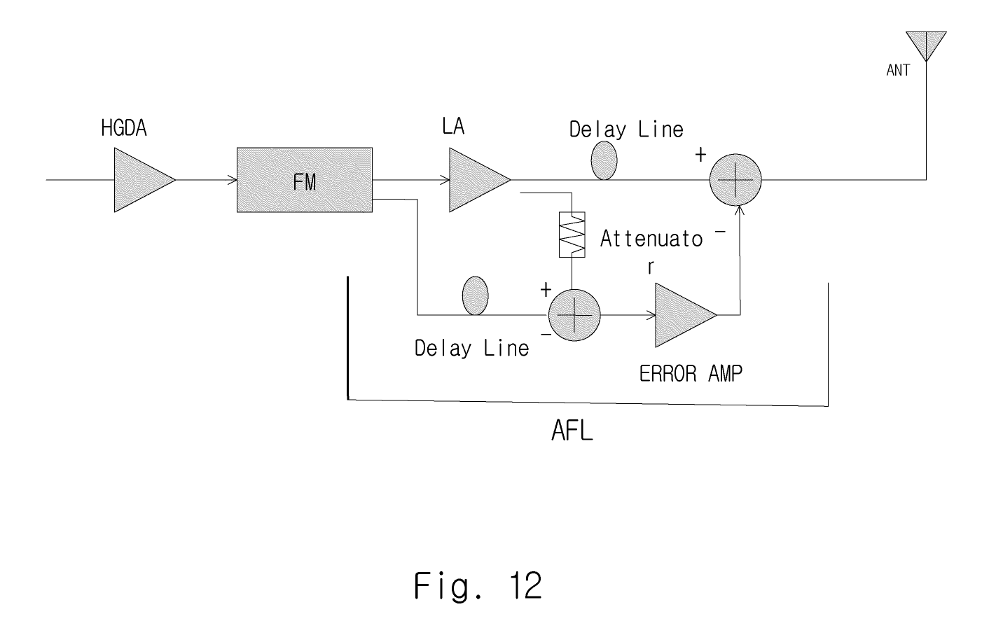

FIG. 12 shows the use of the AFL method combined with the HGDA-FM-LA combination to further improve the output signal from the LA. FIG. 12 shows components of the AFL of FIG. 11 incorporated with the HGDA-FM-LA combination. FIG. 12 shows a small percentage of the signal from the FM directed to the AFL, along with a small percentage of the signal from the LA to produce an output signal at the second adder that is much improved. There is a connection between the filter module and the first adder to receive and deliver the small percentage of the processed first amplified signal from the filter module to the first adder. The attenuator is connected to the LA to receive a percentage of the second amplified signal from the LA. The attenuator is connected to the first adder to deliver a processed second amplified signal to the first adder. The error amplifier is connected to the first adder to receive a first combined signal which was formed from the processed first amplified signal and processed second amplified signal. The second adder connected to the error amplifier and the LA receive and combine an amplified first combined signal from the error amp and the second amplified signal to produce the output signal.

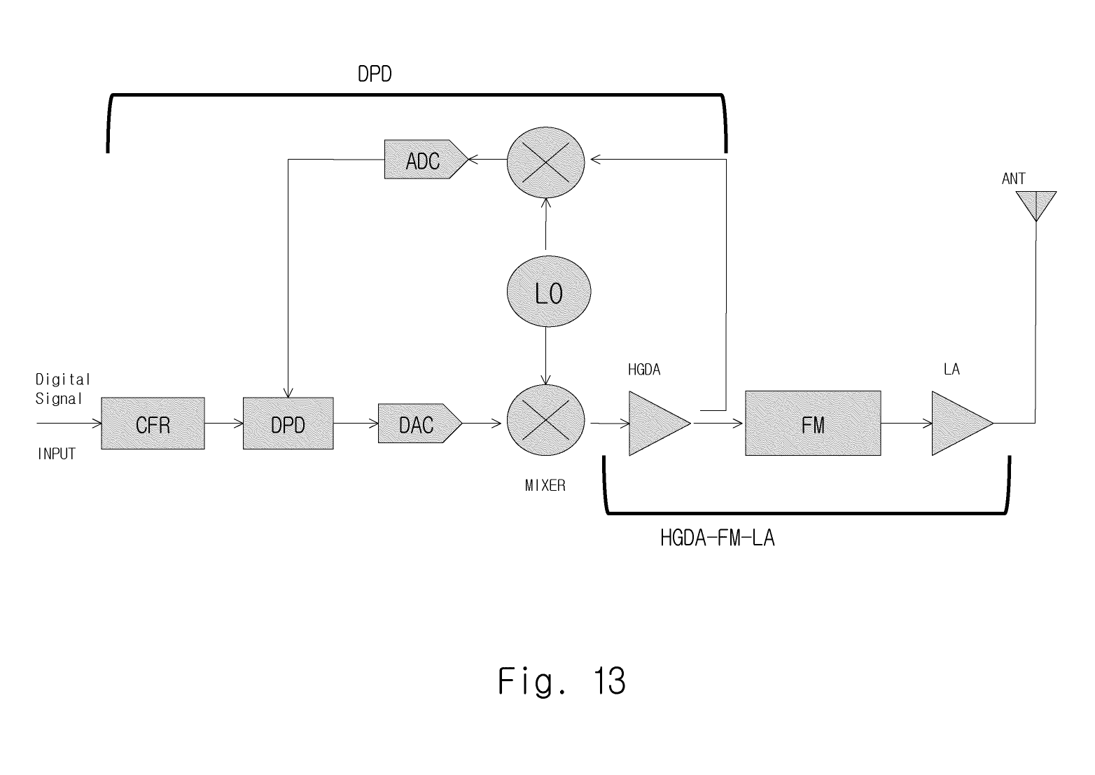

In some communication units, the input signal to be amplified in an amplification system of the communication unit is from a digital source, instead of an analog RF signal from an antenna. For example, the signal to be outputted can be delivered by a fiber optic cable and must eventually be converted to an analog signal for wireless transmission. FIG. 13 shows the DPD used with HGDA-FM-LA combination. The DPD of FIG. 13 is the same as the DPD of FIG. 8. In the case of FIG. 13, the DPD receives a digital input signal as the initial input signal and receives the feedback signal from the HGDA instead of the LA, but in the same manner. The digital input signal in this case does not have to be converted to be used with the DPD and is feed directly to the CFR. Then, the signal is converted to an analog signal and adjusted using up converting frequency mixer that is connected to an LO before reaching the HGDA. The interconnection of the DPD of FIG. 13 employs the use of a LO and frequency mixing device as shown in FIG. 8, instead of the adder shown in FIG. 10. The feedback signal is adjusted using down converting frequency mixer before reaching the ADC. In the alternative, the feedback signal can be taken from the LA instead of the HGDA. Also, the configuration of FIG. 13 can be used where an analog RF input signal is converted to a digital form to become the digital input signal and using the HGDA or LA for the taking the feedback signal.

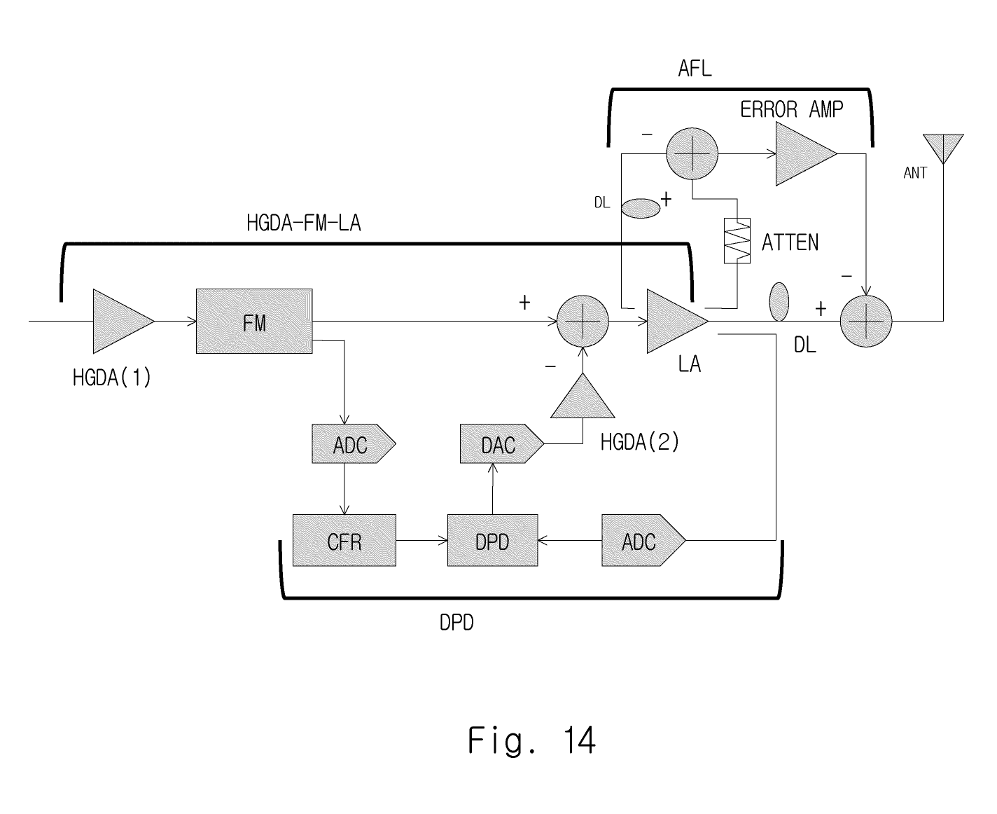

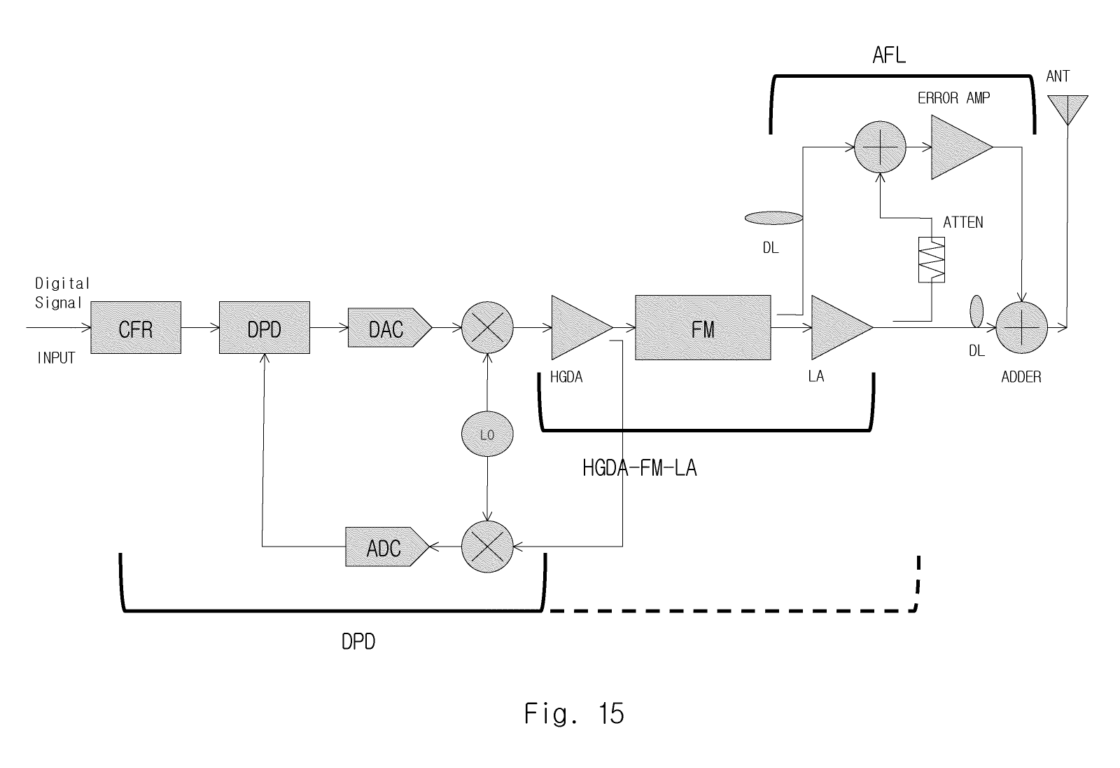

FIG. 14 shows the HGDA-FM-LA combination combined with the DPD circuit of FIG. 10 and the AFL circuit of FIG. 12 to maximize enhancement of the RF power output efficiency of the HGDA-FM-LA combination. Note, both feedback signals for the DPD and AFL are obtained from the output of the LA. The three methods have a similar goal of enhancing the efficiency, but they act on the different locations and the different connections between the input and output of the amplification system. The HGDA-FM is acting on the input side of the LA connected in a series manner. The DPD is acting on the input side of the LA connected in parallel manner, and AFL is acting on output side of LA in a series connection manner. Consequently, all three different techniques having same the goal have a synergy effect enhancing the efficiency of the LA, without the addition of signal interferences among them. FIG. 15 shows the HGDA-FM-LA combination of the present invention combined with the DPD circuit of FIG. 13 and the AFL circuit of FIG. 12. In FIG. 15 the DPD is in series and accepts the digital signal, as was described for FIG. 13. As was for the embodiment of FIG. 13, the feedback signal for the DPD can come from either the HGDA or the LA.

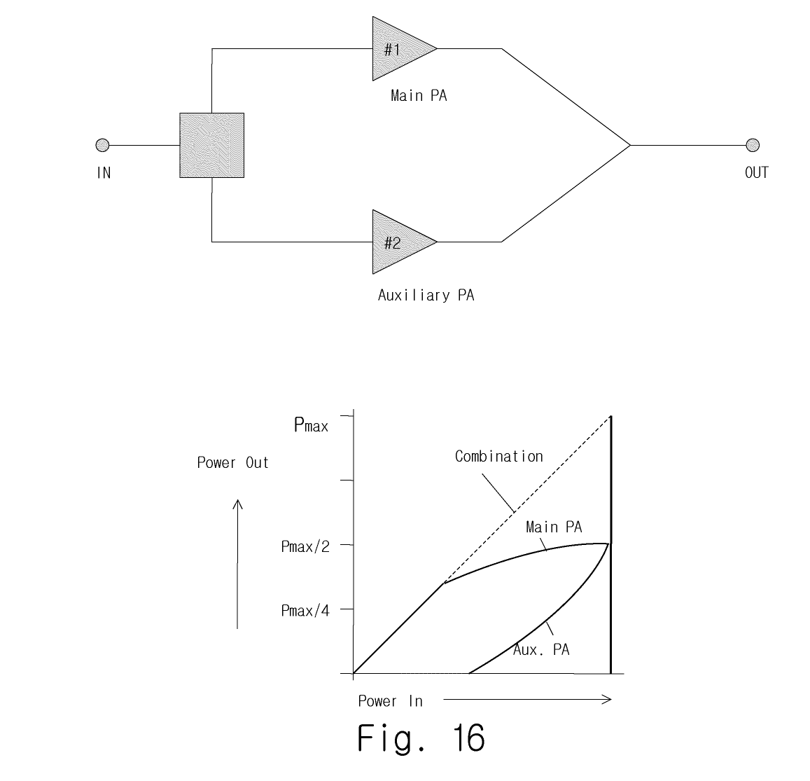

The HGDA-FM-LA combination can be combine with a more efficient amplifier, know as the Doherty amplifier. The Doherty amplifier is based on improving the linearity of RF output power amplifier response by combining two complementary amplifiers in parallel manner. Therefore, the Doherty amplifier can be operated under close to an optimum efficiency condition at near its saturation point without significant power spectrum growth of output signal due to the Inter-Modulation Distortion (IMD). FIG. 16 depicts the schematic design and a graphical representation of how the Doherty amplifier works. The schematic design shows an IN node for an input signal. The signal is split and amplified by a main PA and an auxiliary PA. The signal is then combined for output. The graphical representation shows that the main PA operates near it saturation point, where the power out increases at less of a rate compared to the power in. While, the Auxiliary PA operates such that the power out increases at more a rate as compared to the power in. When signals from the two amplifiers are combined, a signal is produce as shown by the dotted combination line. Detail explanations on this subject can be found in reference, “RF Power Amplifiers for Wireless Communications”, by Steve C. Cripps, Chapter 8, Artech House Inc. 1999.

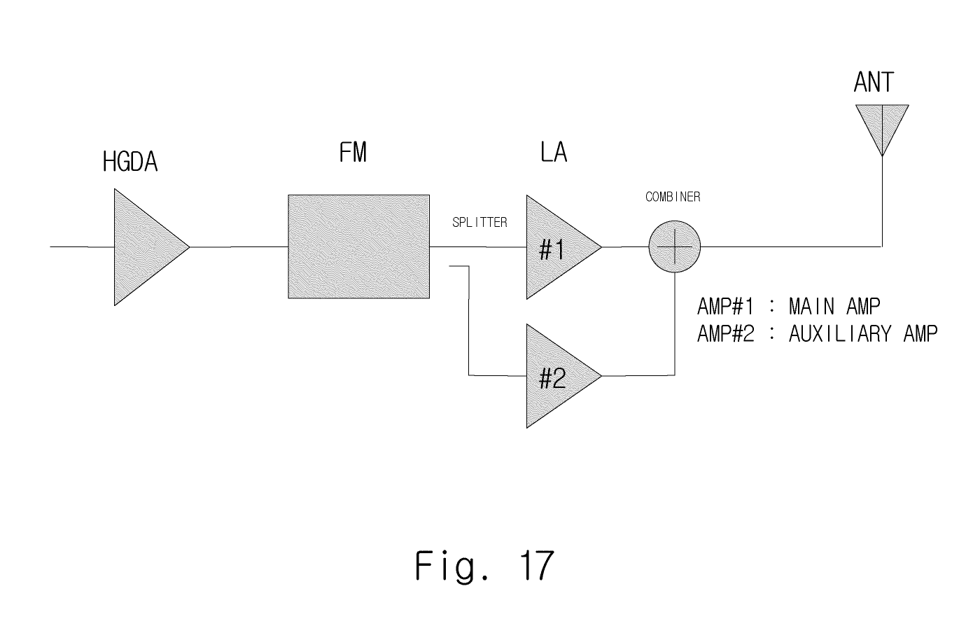

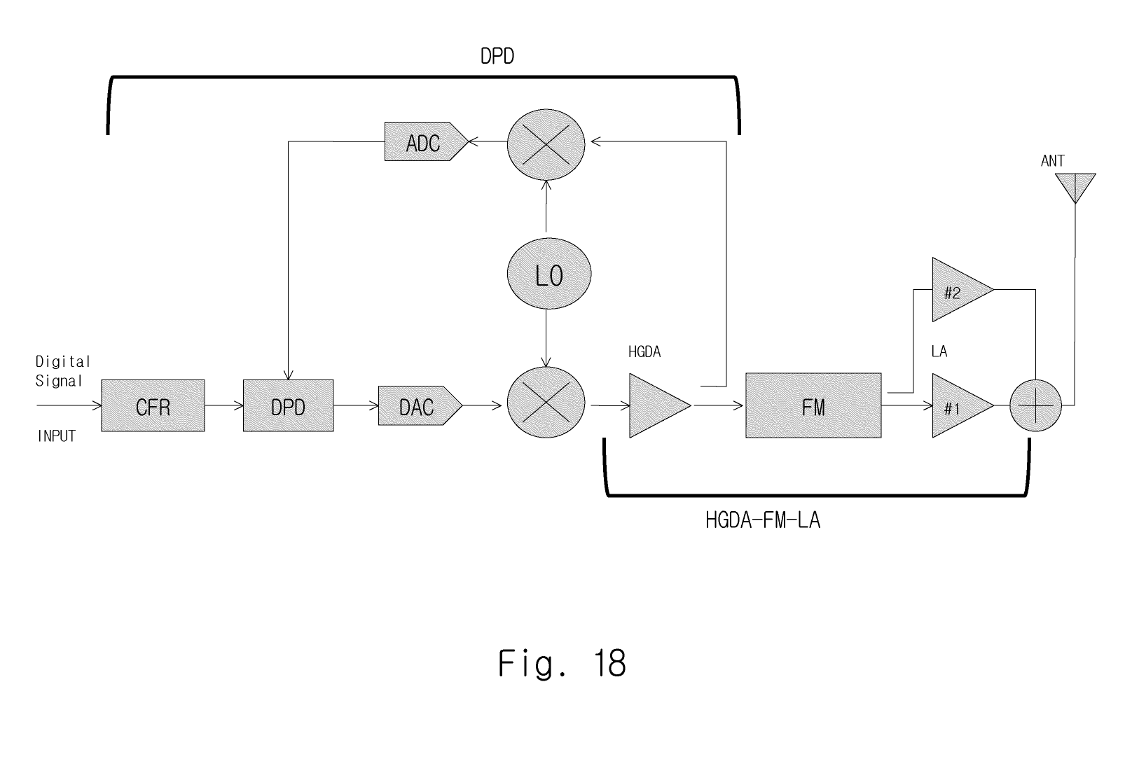

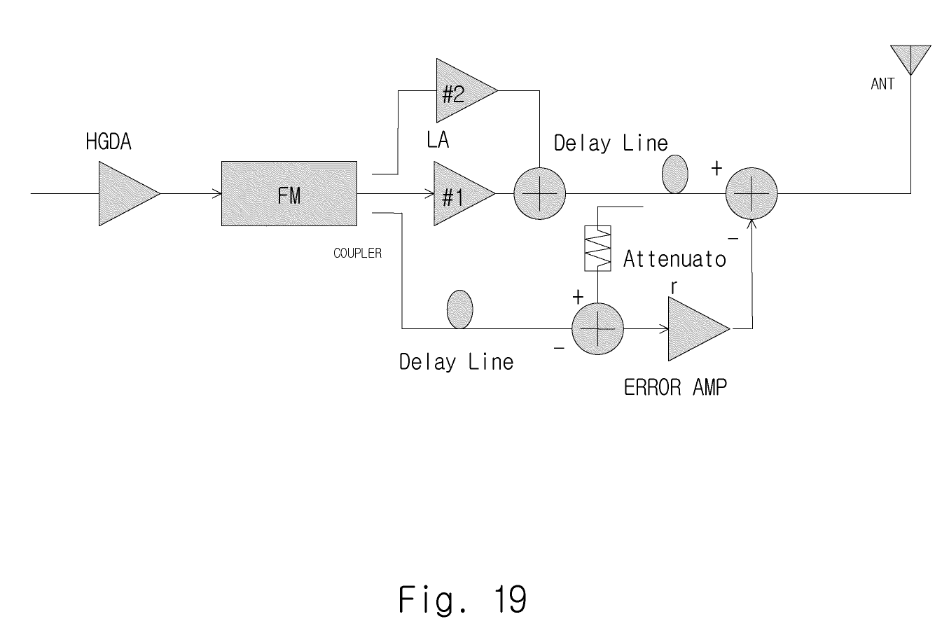

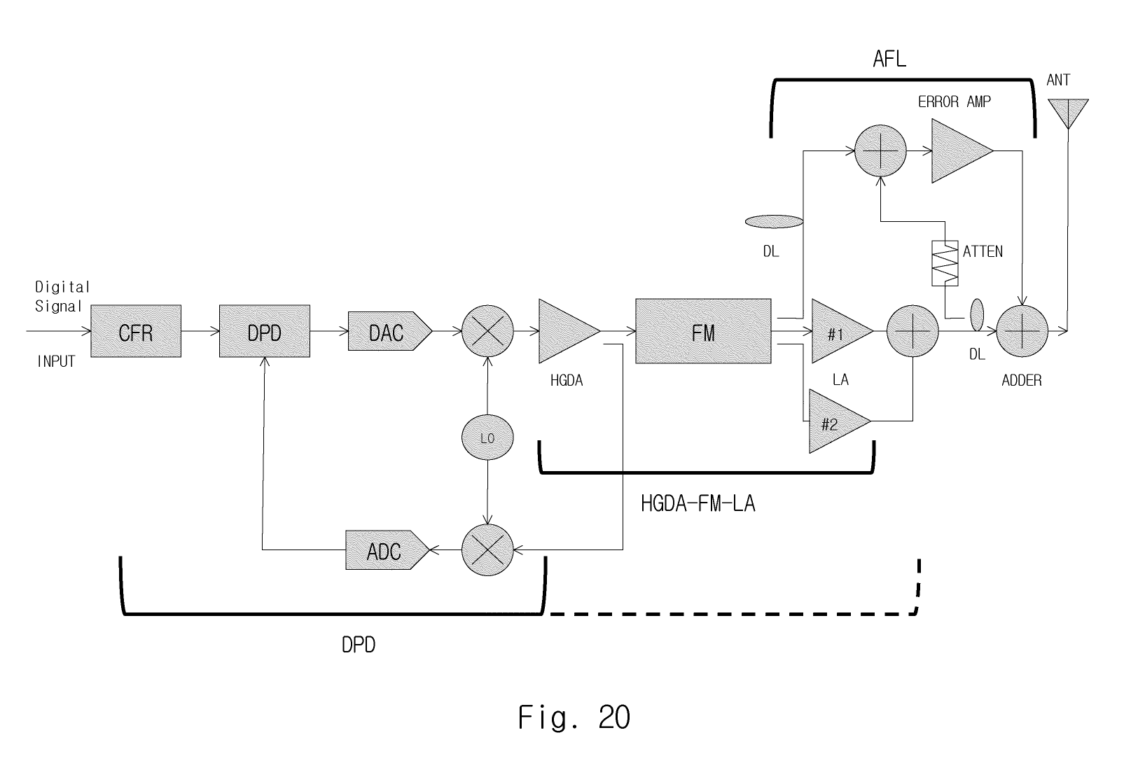

FIG. 17 shows a Doherty amplifier used as the LA, where there the main amplifier and the auxiliary amplifier. The signal is split at the FM and directed to both the main amplifier and the auxiliary amplifier. The outputs from the main amplifier and the auxiliary amplifier are then combined at the adder to produce the output signal to the antenna. Both the main amplifier and the auxiliary amplifier should have the same gain and that gain should be the gain in signal strength desired at the LA position. The Doherty amplifier contributes in two ways when used for the LA. The first way is to enhance the efficiency of the RF power output by improving the linearity of characteristics of an amplifier unit using two complementary amplifiers connected in parallel manner. The second way is to increase level of output power close to twice value of Class B or Class AB power amplifiers with the same gain, because it contains two power amplifiers connected in parallel manner which is one way to increase output power level. FIG. 18 shows the Doherty amplifier replacing the LA for the DPD and HGDA-FM-LA combination shown in FIG. 13. FIG. 19 shows the Doherty amplifier replacing the LA for the AFL and HGDA-FM-LA combination shown in FIG. 12. FIG. 20 shows the Doherty amplifier replacing the LA for the DPD, AFL and HGDA-FM-LA combination shown in FIG. 15.

For the wide band amplification, the antenna, the pre-distortion and the feed forward, are necessary to operate properly in the wide band of the white space applications. Applying the concepts of FIGS. 4-20, FIG. 3 shows the applications of the concepts of FIGS. 4-20 together in a simple form. ANT 32 represents an input antenna as the input source to receive an RF signal and ANT 34 represents an output antenna to output an RF signal from the communication station. PBAR FILTER BANK 14 represents the switching input circuit of FIG. 1 and is controlled by the CR/SDR/CPU type computer as to which frequency is accepted from the ANT 32 to be passed to the PD ENGINE. The PD ENGINE incorporates all of the functions of the CFR, DPD, ADC, and DAC shown in FIG. 20. The PD ENGINE can also incorporate pre-distortion processing of analog signals. The HGDA of FIG. 3 is the same as the HGDA of FIG. 20 and includes the feed back loop shown in FIG. 20. PBAR FILTER BANK 16 represents the switching output circuit of FIG. 2 and is synchronized to the PBAR FILTER BANK 14 so that the CR/SDR/CPU allows the same frequency to pass from the ANT 32 to the LA. The PBAR FILTER BANK 16 performs the same operations as the FM of FIGS. 4-20. The LA and the AFL of FIG. 3 are the same as the LA and AFL of FIG. 20 and perform the same functions, where the AFL is coupled to the output of PBAR FILTER BANK 16. CR/SDR/CPU provides controlling operations of switching to PBAR FILTER BANKs 14, 16, the PD, HGDA, LA and AFL.

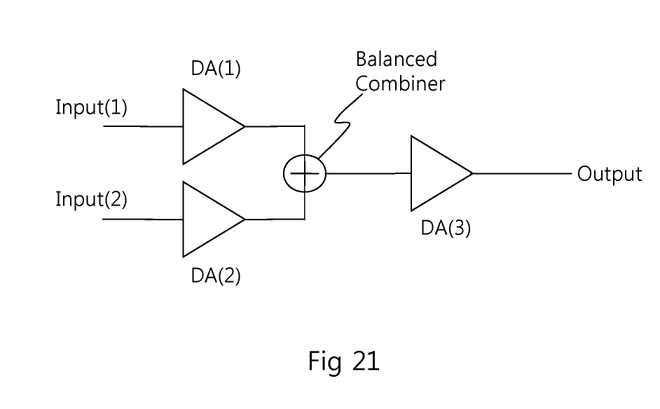

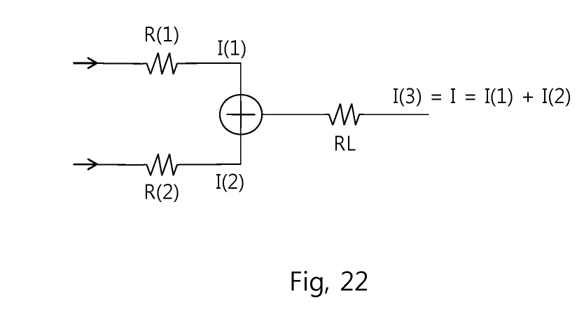

A further improvement to the flexible wireless network is the use of in phase two signal combining FIG. 21 shows a schematic diagram of two driving power amplifiers, DA(1) and DA(2), connected in parallel manner, and the final power amplifier DA(3). Together, DA(1), DA(2) and DA(3) can act as the HGDA. Taking out two small identical signals from the PD Engine compare to taking out one signal for the input, does not require much energy relative to high power side circuits. The principles of square law detection and amplitude superposition of in-phase coherent wave combination are described in details in reference, “Waves”, by F. S. Crawford, Jr., Berkeley physics course, Vol. 3, Mcgraw-Hill Book Co. 1968. The power amplifiers DA(1) and DA(2) can be modeled as an ideal current source, I(i), and a linear resistive Impedance, i.e., R₀=R₁=R₂, and R_{L}=Load Impedance. The driving amplifier DA(3) represents the square law detector described in “Waves” reference. FIG. 22 shows the equivalent circuit of FIG. 21 according to an ideal model of power amplifier.

Let us set two RF signals from DA(1) and DA(2) are identical, so the frequency and amplitude are same for convenience;

I(1)=I(2)=A sin(wt) (1)

, where A, w, and t, are an amplitude, angular frequency, and time, respectively.
The output power from the DA(1), and DA(2), can be written as,

P(1)=[I(1)]²×R₁=[A sin(wt)]²×R₀, (2)

And

P(2)=[I(2)]²×R₁=[A sin(wt)]²×R₀, (3)

, since R₁=R₂=R₀.
If two RF signals from the DA(1) and DA(2) of Equation 1, are added RANDOMLY, i.e., not IN-PHASE manner, then the total combined power from two DA(1) and DA(2), becomes,

P(T)=P(1)+P(2)=2[A sin(wt)]²×R₀=2[A sin(wt)]²×R_{L} (4)

### , for R₀=R_{L}.

However if two RF signals from the DA(1) and DA(2) are combined IN-PHASE manner, then the total combined output power, becomes,

$$\begin{matrix}P ( T ) = {[ I ( 1 ) + I ( 2 ) ]}^{2} \times {R}_{L} \\ = {[ A sin ( wt ) + A sin ( wt ) ]}^{2} \times {R}_{L} \\ = {[ 2 A sin ( wt ) ]}^{2} \times {R}_{L} \\ = {4 [ A sin ( wt ) ]}^{2} \times {R}_{L}\end{matrix} \qquad ( 5 )$$

The total power of the IN-PHASE signal combination of Equation 5 is twice as large as that of RANDOM signal adding of Equation 4.

Let us evaluate the above two cases of RANDOM and IN-PHASE combination of two identical signals, in terms of the total output power efficiency and the quality of ACLR of output RF signal of the mobile communication equipment. First for output power efficiency, the power efficiency can be defined as EFFI=P(0)/P(I), where P(0) and P(I) are the total output RF power and the total input DC power of the unit under test. For the RANDOM adding of two identical signals,

P(0)=[I(1)²×R₀]+[I(2)²×R₀]=2×[I(1)]²×R_{L} (6)

So the total output power efficiency becomes,

P(O)/P(I)={2×[I(1)]²×R_{L}}/P(I) (7)

And for the IN-PHASE two signals combination,

P(O)=[I(1)+I(2)]²×R_{L}=4×[I(1)]²×R_{L} (8)

So the total output power efficiency becomes,

P(O)/P(I)={4×[I(1)]²×R_{L}}/P(I) (9)

The output power efficiency of Equation 9 for the IN-PHASE combination is two times as large as that of the Equation 7 for the RANDOM adding under the ideal approximation. The total output RF signal efficiency of two signals IN-PHASE combination is superior to that of RANDOM adding of two signals.

Let us set the magnitude of input signal and noise level as 5 dB and 1 dB, respectively, to evaluate the quality of output RF signal of ACLR. The ACLR of this example becomes 5 dB−1 dB=4 dBc. The magnitude of output signal and noise level after RANDOM adding of two identical input signals becomes 8 dB and 4 dB, respectively, because of 2 times of magnitude in dB is identical to +3 dB from Equation 4. So 5 dB+3 dB=8 dB and 1 dB+3 dB=4 dB for the magnitude of signal and noise, respectively. The ACLR is 8 dB−4 dB=4 dBc. The magnitude of output signal and noise level after IN-PHASE Coherent Wave combination of two identical input signals, becomes 11 dB and 4 dB, respectively, because of 4 times magnitude in dB is identical to +6 dB from Equation 5. Notice that the noise can be only added in RANDOM because of its intrinsic nature of randomness. The ACLR is 11 dB-4 dB=7 dBc. The ACLR of IN-PHASE combined two identical input signals is always 3 dBc better than that of RANDOM added, which leads to higher bit rates of digital modulation in wireless communication. Therefore the quality of output RF signal of the IN-PHASE combined is much superior than that of the RANDOM added. It is clear that superior output power efficiency and ACLR would result by utilizing the IN-PHASE combining of two identical RF signals of the relatively higher quality signals than the lower quality signals.

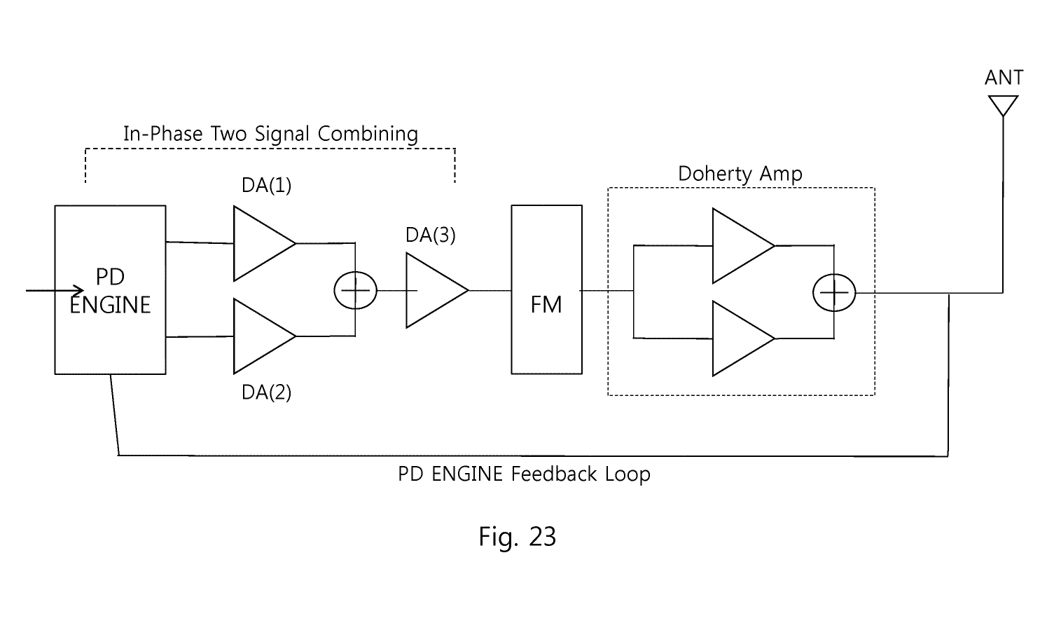

The IN-PHASE combining of two identical RF signals can be incorporated into Digital Pre-Distortion (DPD), Adaptive Pre-Distortion (APD), and Doherty Amplifier, and Adaptive Feed Forward Linearization (AFL) techniques. FIG. 23 shows the output power module with APD(or DPD), FM, and an asymmetry Doherty amp in addition to in-phase coherent two signal wave combination of FIG. 22 to enhance the output power efficiency. The general Pre-Distortion is well explained in reference, “RF and Microwave Circuit Design for Wireless Communication”, Edited by L. E. Larson, Artech House(1996), Chapter 4. The Adaptive Pre-Distortion(APD), which is an analog pre-distortion process, is recent development and described in detail in reference, U.S. Pat. No. 7,026,873 B2, Apr. 11, 2006, “LMS-Based Adaptive Pre-Distortion for Enhanced Power Efficiency”, Assignee: Scintera Networks, San Jose, Calif. The Doherty Amplifier is also described well in reference “RF Power Amplifiers for Wireless Communications”, by S. C. Cripps, Artech House(1999), Chapter 8. The Digital Pre-Distortion(DPD), an Adaptive Pre-Distortion(APD) and the Doherty Amplifier(both Symmetry and Asymmetry) have been developed to extend the linear response of power amplifiers (PAs) and consequently improve the efficiency of the PAs. The phases of two identical signals can be adjusted to be in phase at the PD Engine before outputting the from the PD Engine. For example, taking a 10 db signal with 6 db noise from the PD Engine provides an ACLR of 10 db−6 db=4 db. When the 10 db signal with 6 db noise is split into two signals of 7 db with 3 db of noise for DA(1) and DA(2) that are in phase, you get a DA(3) output of 13 db with 6 db of noise. This provides an ACLR of 13 db—6 db=7 db, which is higher than the 3 db when only using one signal.

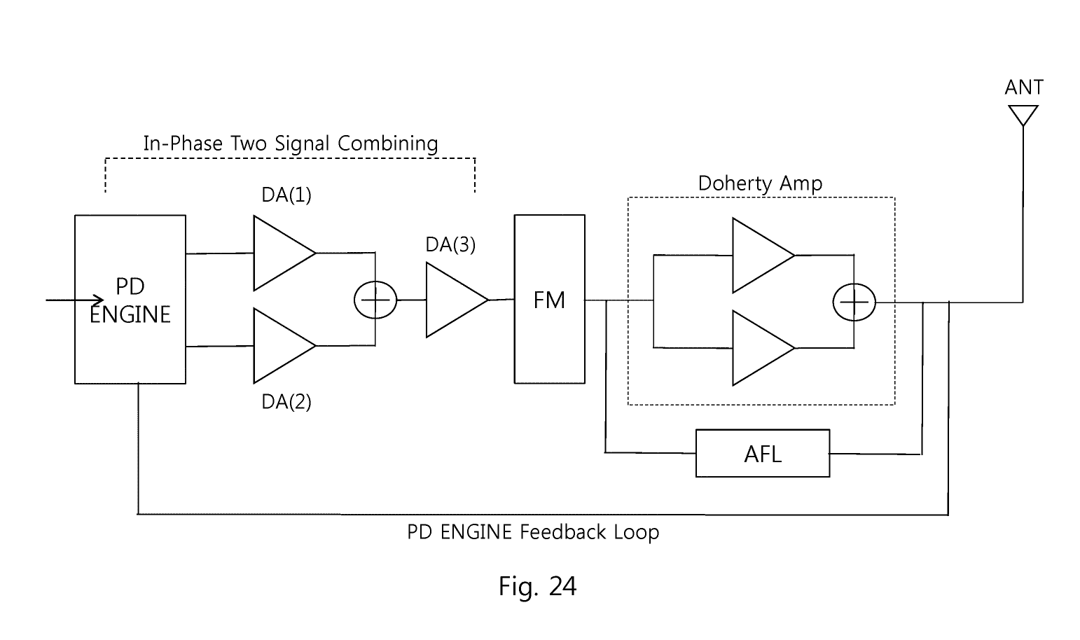

The use of the FM not only improves the quality of input signal, S/N ratio to the final power amp, but also suppresses unnecessary parasitic oscillation coming from usually high power and high gain Doherty amplifiers. FIG. 24 is a schematic diagram of the advanced output power module of FIG. 23 with the AFL incorporated. The adaptive feed forward technique also well established technique for enhancing the output power efficiency by direct linearization of output signal. The Adaptive Feed Forward Linearization (AFL) in FIG. 24 would be much more effective than in the conventional configuration. The AFL in a conventional wireless output power module, the power consumption of the error amplifier in AFL circuit, becomes significantly large. One of the reason for this is due to the gain of final Doherty Amplifier, which is usually about 50 dB. In order to match and cancel the noise from the main Doherty Amp, the noise signal also need to be amplified to the same magnitude. Therefore the gain of error amplifier should be about 50 dB. But in use with the FM, the gain of final asymmetry Doherty Amp is not more than 20 dB. In addition to this relatively lower gain of about 15 dB for the error amp in FIG. 24, compared to 50 dB for the conventional error amp in an AFL circuit, the magnitude of noise signal for the configuration shown in FIG. 24 is much smaller than that of the conventional power module, as has been discussed throughout text and in previous patents. Consequently the magnitude of noise signal in of the system shown in FIG. 24 is rather small, so the error amplifier does not need to consume a big power to amplify the noise signal to match the noise signal generated in the main asymmetry Doherty amp. The output power efficiency enhancing methods of coherent in-phase two input signals combination, APD (or DPD), and FM are designed to improve the quality of the input RF signal (i.e., for larger ACLR and smaller EVM) before feeding into the final Asymmetry Doherty Amplifier with AFL. The asymmetry Doherty Amp and AFL is improving the linear response of power amp itself and output RF signal.

If the Doherty amp is designed (by using the higher output power Transistor in dBm and selecting the lager value of PAR=Peak-to-Average Power Ratio in dB) to operate in a linear region to amplify the input RF signal, of which quality is improved already to very high level by the previous enhancing techniques, and the AFL is tuned accordingly, then the quality of the final high power RF signal also becomes very high. However the output power efficiency would be a little smaller than otherwise because of the final Doherty amp is designed to operate in the linear response region than in normally operated maximum efficiency region. One can choose to design the output power module of FIG. 23 for either maximum optimization for the output power efficiency with normally accepted output signal quality ACLR and EVM values or optimizing the higher output signal quality for superior ACLR and EVM values by sacrificing the output power efficiency. The asymmetry Doherty Amp and AFL is basically working on the improvement of the linear response of power amp itself and output RF signal, respectively. If the Doherty amp is designed by using the higher power Transistor and selecting the larger value of PAR to operate in a linear region to amplify the input RF signal and the AFL is tuned accordingly, then the quality of the final high power RF signal also becomes very high. However the output power efficiency would be a little smaller than otherwise because of the final Doherty amp is designed to operate in the linear response region than in normally operated maximum efficiency region. One can also choose to design the output power module of FIG. 24 for either maximum optimization for the output power efficiency with normally accepted output signal quality ACLR and EVM values or optimizing the higher output signal quality for superior ACLR and EVM values with a cost of the smaller output power efficiency relative to the (1) case.

The present invention is a multi mode power output module and method of use for use with wireless equipment. The multi mode power output module allows the use of different types of signal power output circuits which can be incorporated into one piece equipment with high output power efficiency achieved for lower power requirements as well as high power requirements. The flexible wireless network system includes advanced switching and amplification to increase power output with high efficiency and quality of RF signals used with wireless networks, as described above. The flexible wireless network system would benefit from being able to operate at different power levels. Two or more different output power levels, low to high from one piece of wireless equipment in a communication unit with high output power efficiency is a solution for power required to handle normal service and then handle demand for increase power when needed. Two wireless output power requirements usually have distinctively different characteristics and are connected such a way to operate dynamically responding to the complex heavy data traffic demands in real time. To maximize the overall quality of services with the highest output power efficiency of a wireless network system, the wireless equipment with a multi mode power output module of the present invention would satisfy such a requirement.

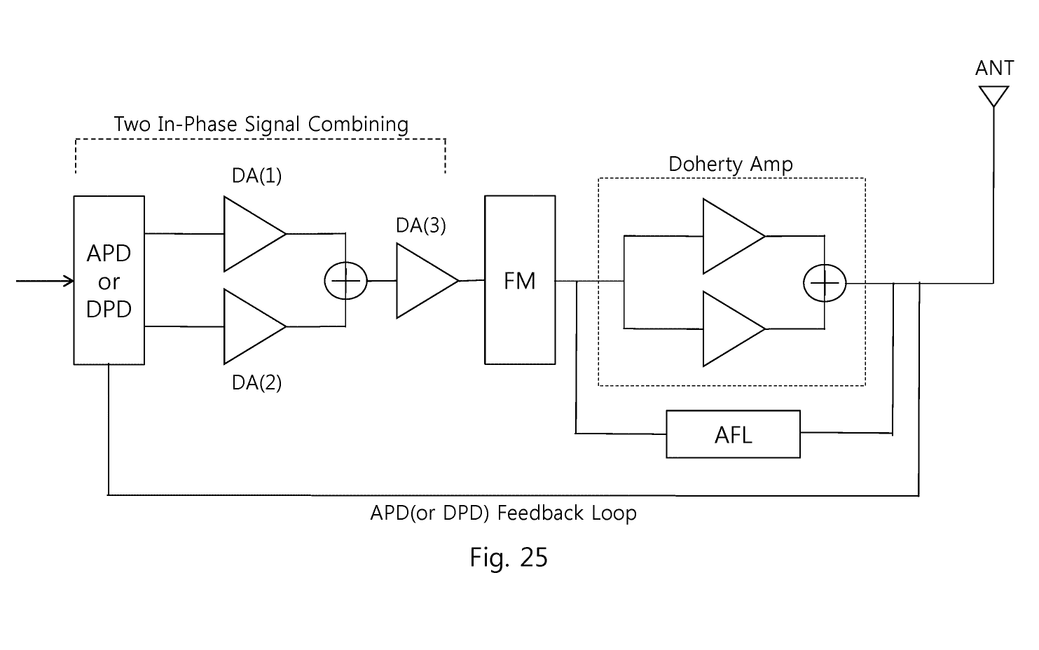

FIG. 25 shows a schematic diagram of an advanced output power module which can be optimized in terms of both the output power efficiency or/and the quality of output RF signal. DA represents Driving Amplifier and the APD and DPD are Pre-distortion engines in FIG. 25. The output power efficiency enhancing methods of coherent in-phase combining of two input signals, APD, DPD are designed to improve the quality of the input RF signal, i.e. larger ACLR and smaller EVM values, to the final Asymmetry Doherty Amplifier and AFL. The filter module (FM) is includes one or more Band Pass Filters (BPF) or bulk acoustic resonators. The FM can also include additional components to improve the signal processing of an input RF signal. The one or more BPF of the FM are used to improve the input RF signal to meet ACLR requirements. The FM is designed to produce an extremely clean signal with specific properties depending on the frequency bandwidth to pass through the FM. The FM contributes to suppress an unnecessary parasitic oscillation coming from usually high power and high gain output power Amp such as the Doherty Amplifier. The asymmetry Doherty Amp and AFL works on the improvement of the linear response of a power Amp itself and output RF signal, respectively. The FM, BPF, bulk acoustic resonators, asymmetry Doherty Amp and AFL have all been described in more detail above.

The Doherty Amp can be designed by using the higher output power Transistor in dBm and selecting the lager value of PAR=Peak-to-Average Power Ratio in dB to operate in a linear region to Amplify the input RF signal, where the quality of the input signal has already been improved to very high before the input RF signal reaches the Doherty Amp. However, when the power output is lower, the output power efficiency decreases because the final Doherty Amp is designed to operate in the linear response region that uses the higher power output to provide maximum efficiency. Therefore, the output power module of FIG. 25 can be designed for either maximum optimization for the output power efficiency with normally accepted output signal quality or optimizing for a higher output signal quality by sacrificing the output power efficiency.

The Adaptive Feed Forward Linearization (AFL) shown in FIG. 25 would be much more effective than in the conventional wireless output power module. For the AFL in a conventional wireless output power module, the power consumption of the error Amplifier in the AFL circuit becomes significantly large. One of the reasons for this is due to the gain of final Doherty Amplifier, which is usually about 50 dB. In order to match and cancel the noise from the main Doherty Amp, the noise signal also need to be Amplified to the same magnitude. Therefore the gain of error Amplifier should be about 50 dB. But in the systems that can handle higher power outputs, the gain of final asymmetry Doherty Amp is not more than 20 dB. In addition to this relatively lower gain of about 15 dB for the error Amp in FIG. 25 as compared to 50 dB for the conventional error Amp in the AFL circuit, the magnitude of noise signal in of the module shown in FIG. 25 is much smaller than that of the conventional power module. Consequently the magnitude of noise signal in the module shown in FIG. 25 is rather small, so the error Amplifier does not need to consume a large amount of power to Amplify the noise signal to match the noise signal generated in the main asymmetry Doherty Amp.

The Error Vector Magnitude (EVM) is an important parameter indicating the quality of output RF signal along with ACLR. It represents the linearity of both Amplitude and phase of an output signal. It is influenced by both the quality of input signal to the final output power Amplifier and the characteristics of final output power Amplifier of asymmetry Doherty Amp. If a very high quality input RF signal is Amplified by the final Doherty Amp in linear region, then the quality of high power output RF signal also is high relative to Amplify in non-linear region. In general the higher bit rates can be obtained with a higher quality output signal having larger ACLR and smaller EVM values in a wireless system. Meaning, information delivery capacity of a wireless network becomes larger with a higher bit rate using proper modulation.

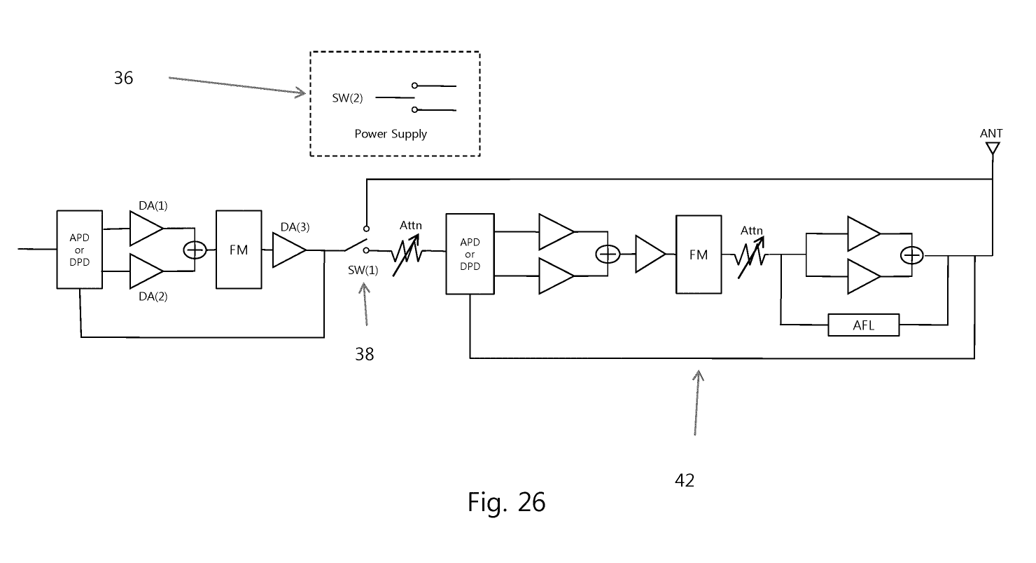

FIG. 26 is a schematic diagram of a multi-mode output power module connected in series, including coherent two signals In-Phase combination, APD or DPD, FM, Asymmetry Doherty Amp and AFL of FIG. 25. Notice that there is an FM located in front of both DA(3) and the final power Amplification section of Doherty Amp. The first FM is for the lower output RF power level, for an example, about 43 dBm (20 W) radiation. The second FM is for the higher output power level, for an example, about from 46 dBm (40 W) to 50 dBm (100 W) radiation. The strong demand of cost reduction in both equipment and operation is the trend in recent development of wireless services. Multi Mode RF output power module would be one way to satisfy the market demand.

By having two different levels of optimized output RF power radiated from one unit of equipment instead of two as shown in FIG. 26, cost of the equipment and operation is reduced. Therefore in FIG. 26, the desired output power level can be chosen by switching to higher electrical power with switch 36 closed to high power or switching to lower electrical power with switch 36 closed to low power. When switch 38 is closed to the RF output 40, the high output power circuit including the Doherty AMP for the higher RF output radiation would be open during the lower RF output power operation to save unnecessary DC power consumption by only using the low power circuit. When switch 36 is closed to the higher power, the switch 38 to the high output power circuit 42 would be closed to use the high output power circuit 42.

It is well known that if lower RF output power is radiated from the wireless system output power module optimized for higher RF output power radiation, the efficiency of equipment becomes much lower. With the present invention, both the efficiency of RF output power Amp of DA(3) which is acting as the final output power AMP for lower RF output operation and the efficiency of Doherty Amp for higher output operation can be optimized independently in the same equipment by using the switches 36, 38 in FIG. 26. The independently optimized RF output signal of DA(3) for lower output power operation, which is also the input signal for Doherty AMP, leads to providing the best input signal for optimizing the efficiency of the Doherty AMP for the higher output RF power signal requirement. The Gain of the final Doherty Amp would be chosen to be in the range of magnitude between 8 dB and 14 dB. The DA(3) Amp in FIG. 26 acts as the output power Amp which is optimized for a lower output power level, such as 20 W. The DA(3) Amp can also acts like a square law detector and also can be designed as an asymmetry Doherty Amp type for further improvement of power efficiency. For a lower output power level, using the lower electrical power and removing the high output power circuit from the system using switch saves energy and provides improved output power efficiency. For a higher output power level, taking advantage of the adding in the high output power circuit provides output power efficiency that improved over a system that does not have these capabilities. An example is there is equipment optimized for a 100 W output power level, but at times the equipment operates a 20 W output lower level instead for a certain period time. The output power efficiency for this example becomes quite poor and could be less than 10%. The switching the output power level between 100 W and 20 W can be occurred frequently in real world operations, so that over all energy efficiency of system could be very low due to demands. The multi mode output power module of FIG. 26 improves the energy efficiency of whole wireless system for a complex and demanding service environment. Also as shown in FIG. 26, an attenuator (Attn) could be utilized to adjust the input level of the Doherty AMP to obtain the desired final output level for the higher RF output power operation.

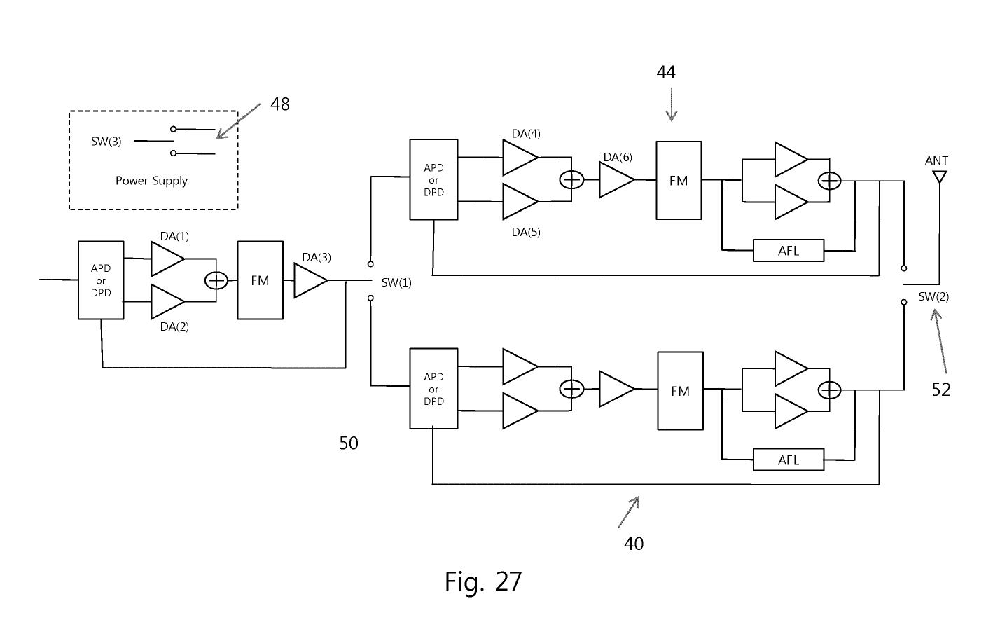

It is envisioned that more than two output power circuits can be used with FIG. 26. FIG. 27 is a schematic diagram of the multi-mode output power module connected in parallel with the identical equipped output power circuits 44, 46. These two output power circuits 44, 46 can be designed to have different characteristics. These two output power circuits 44, 46 are connected in parallel can be driven dynamically in real time by the output signal from the driving section coupled by the programmed switches, similar to the hand-off mechanism of a cell phone. Switch 48 provides the electrical power and switches 50, 52 determine which output power circuit is used. All three switches 48, 50, 52 can be synchronized such a way that only one output power circuit is connected to the main power supply and antenna when chosen. In this system the selected one of two functionally different RF output signals can be radiated in open space at a given time according to the customer demand. Combining the concepts of FIGS. 26 and 27, you can have switching to have a low power output or different high power outputs.

While different embodiment of the invention have been described in detail herein, it will be appreciated by those skilled in the art that various modification and alternatives to embodiments could be developed in light of the overall teachings of the disclosure. Accordingly, the particular arrangements are illustrated only and are not limiting as to the scope of the invention that is to be given the full breadth of any and all equivalents thereof.

I claim:

1. A multi mode power output module, for use with RF signal amplification system, comprising:
at least two power sources, wherein said at least two power sources have a power level that is different from each other;
a multiple of output power circuits associated with each of said at least two power sources to amplify an RF signal, wherein there is an output power circuit associated with a lowest power output level and there is an output power circuit to amplify an RF signal associated with a power output level higher than said lowest power output level;
a first switch to switch between said at least two power sources, where said first switch provides power from at least two power sources to said output power circuit to amplify an RF signal associated with a lowest power output level;
a second switch to switch between an RF output and said multiple of output power circuits to select a output power circuit associated with one of said at least two power sources that is also connected to said RF output.

2. A multi mode power output module of claim 1, further including at least one output power circuit comprising a pre-distortion engine, Doherty amplifier connected to said pre-distortion engine, a filter module connected to said Doherty amplifier, a RF amplifier connected to said filter module and an RF signal output connected to said RF amplifier and connected to said second switch and a feedback loop between said pre-distortion engine and said RF signal output; and further including at least one higher output power circuit comprising a pre-distortion engine connected to said second switch, Doherty amplifier connected to said pre-distortion engine, a RF amplifier connected to said Doherty amplifier, a filter module connected to said RF amplifier, a Doherty amplifier connected to said filter module and an RF signal output connected to said Doherty amplifier and an AFL coupled to a second RF signal output from said FM and connected to said RF signal output and a feedback loop between said pre-distortion engine and said second RF signal output.

3. A multi mode power output module, for use with RF signal amplification system, comprising:
at least two power sources, wherein said at least two power sources have a power level that is different from each other;
a multiple of output power circuits associated with each of said at least two power sources to amplify an RF signal, wherein there is an output power circuit associated with a lowest power output level and there is an output power circuit to amplify an RF signal associated with a power output level higher than said lowest power output level;
a first switch to switch between said at least two power sources, where said first switch provides power from at least two power sources to said output power circuit to amplify an RF signal associated with a lowest power output level;
a second switch to switch between said multiple of output power circuits to select a output power circuit associated with one of said at least two power sources.

4. A multi mode power output module of claim 3, further including a third switch to switch between said multiple of output power circuits and an RF output.

5. A multi mode power output module of claim 3, further including at least one output power circuit between said first switch and said second switch comprising a pre-distortion engine, Doherty amplifier connected to said pre-distortion engine, a filter module connected to said Doherty amplifier, a RF amplifier connected to said filter module and an RF signal output connected to said RF amplifier and connected to said second switch and a feedback loop between said pre-distortion engine and said RF signal output.

6. A multi mode power output module of claim 5, further including a third switch to switch between said multiple of output power circuits and an RF output.

7. A multi mode power output module of claim 3, wherein said multiple of output power circuits include at least one higher output power circuit comprising a pre-distortion engine connected to said second switch, Doherty amplifier connected to said pre-distortion engine, a RF amplifier connected to said Doherty amplifier, a filter module connected to said RF amplifier, a Doherty amplifier connected to said filter module and an RF output connected to said Doherty amplifier and an AFL coupled to a RF output from said FM and connected to said RF signal output and a feedback loop between said pre-distortion engine and said RF output.

8. A multi mode power output module of claim 7, further including a third switch to switch between said multiple of output power circuits and an RF output.

9. A multi mode power output module of claim 5, wherein said multiple of output power circuits include at least one higher output power circuit comprising a pre-distortion engine connected to said second switch, Doherty amplifier connected to said pre-distortion engine, a RF amplifier connected to said Doherty amplifier, a filter module connected to said RF amplifier, a Doherty amplifier connected to said filter module and an RF output connected to said Doherty amplifier and an AFL coupled to a RF output from said FM and connected to said RF signal output and a feedback loop between said pre-distortion engine and said RF output.

10. A multi mode power output module of claim 9, further including a third switch to switch between said multiple of output power circuits and an RF output.

11. A method for use with RF signal amplification system, comprising:
selecting one of at least two power sources, wherein the at least two power sources have a power level that is different from each other;
sending a RF signal to one of a multiple of output power circuits associated with each of the at least two power sources to amplify an RF signal, wherein there is an output power circuit associated with a lowest power output level and there is an output power circuit to amplify an RF signal associated with a power output level higher than the lowest power output level;
selecting a position of a first switch to switch between the at least two power sources, where the first switch provides power from at least two power sources to the output power circuit to amplify an RF signal associated with a lowest power output level;
selecting a position of a second switch to switch between an RF output and the multiple of output power circuits to select a output power circuit associated with one of the at least two power sources that is also connected to the RF output.

12. The method of claim 11, further including at least one lower output power circuit comprising components of a pre-distortion engine, Doherty amplifier connected to the pre-distortion engine, a filter module connected to the Doherty amplifier, a RF amplifier connected to the filter module and an RF signal output connected to the RF amplifier and connected to the second switch and a feedback loop between the pre-distortion engine and the RF signal output; and further including at least one higher output power circuit comprising components of a pre-distortion engine connected to the second switch, Doherty amplifier connected to the pre-distortion engine, a RF amplifier connected to the Doherty amplifier, a filter module connected to the RF amplifier, a Doherty amplifier connected to the filter module and an RF signal output connected to the Doherty amplifier and an AFL coupled to a second RF signal output from the FM and connected to the RF signal output and a feedback loop between the pre-distortion engine and the second RF signal output and sending the RF signal through the components to produce a modified RF signal.
